(19) United States
(12) Patent Application Publication
(10) Pub. No.: US 2025/0323679 A1
(43) Pub. Date: Oct. 16, 2025

(54) DUAL CONNECTIVITY RADIO FREQUENCY FRONT END ARCHITECTURE

(71) Applicant: Skyworks Solutions, Inc., Irvine, CA (US)

(72) Inventor: David Richard Pehlke, Westlake Village, CA (US)

(21) Appl. No.: 19/175,552

(22) Filed: Apr. 10, 2025

Related U.S. Application Data
(60) Provisional application No. 63/633,568, filed on Apr. 12, 2024.
(60) Provisional application No. 63/643,860, filed on May 7, 2024.

(51) Int. Cl. H04B 1/44; H03F 3/24

(52) U.S. Cl. CPC H04B 1/44; H03F 3/245; H03F 2200/451

(57) ABSTRACT

Aspects of this disclosure relate to radio frequency front-end modules that can transmit sounding reference signals for determining a channel model for an antenna without interrupting an anchor link established by the antenna. The radio frequency front-end modules can include a radio frequency switch configured, during an antenna calibration period, to simultaneously pass one or more sounding reference signal symbols to a first antenna and pass primary and diversity downlink signals from an antenna to a first receive amplifier and pass the diversity downlink signals from a second antenna to a second receive amplifier. Related methods, radio frequency systems, radio frequency modules, and wireless communication devices are also disclosed.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and wearable electronics.

### SUMMARY

In some aspects, the techniques described herein relate to a radio frequency front-end module including: a first transmit amplifier configured to output first uplink signals over a first frequency band, and a second transmit amplifier configured to output second uplink signals over a second frequency band; a first receive amplifier configured to receive primary downlink signals over the first frequency band, and a second receive amplifier configured to receive diversity downlink signals over the first frequency band; and a radio frequency switch configured, during an antenna calibration period, to simultaneously: pass the second uplink signals corresponding to one or more sounding reference signal symbols to a first antenna, pass the primary downlink signals from the first antenna to the first receive amplifier, and pass the diversity downlink signals from a second antenna to the second receive amplifier.

In some aspects, the techniques described herein relate to a radio frequency front-end system including the radio frequency front-end module and a second radio frequency front-end module coupled to the radio frequency front-end module to receive the second uplink signals, the second radio frequency front-end module including: a third receive amplifier configured to receive third downlink signals over the first frequency band, and a fourth receive amplifier configured to receive fourth downlink signals over the first frequency band; and a second radio frequency switch configured, during another antenna calibration period, to simultaneously: pass the second uplink signals corresponding to one or more second sounding reference signal symbols to a third antenna, pass the third downlink signals from the third antenna to the third receive amplifier, and pass the fourth downlink signals from a fourth antenna to the fourth receive amplifier.

In some aspects, the techniques described herein relate to a radio frequency front-end system including: a first radio frequency module configured to transmit first uplink signals over a first frequency band and second uplink signals over a second frequency band, and receive primary and diversity downlink signals over the first and second frequency bands, the first radio frequency module including a first radio frequency switch configured to: pass first primary downlink signals and first diversity downlink signals within the first frequency band from at least one of a first antenna and a second antenna to one or more receive amplifiers; pass second primary downlink signals and second diversity downlink signals within the second frequency band from at least one of the first and second antennas to the one or more receive amplifiers; and during an antenna calibration period, simultaneously transmit a first sounding reference signal to the first antenna and pass a primary or a diversity downlink signal from the first antenna to the one or more receive amplifiers.

In some aspects, the techniques described herein relate to a radio frequency front-end system wherein the first radio frequency switch passes the first sounding reference signal to the first antenna without interrupting an anchor link established based on the first antenna.

In some aspects, the techniques described herein relate to a radio frequency front-end system wherein the first sounding reference signal is usable for determining a channel model for the first antenna.

In some aspects, the techniques described herein relate to a radio frequency front-end system wherein the one or more receive amplifiers include: first and second primary amplifiers configured to receive first and second primary downlink signals, respectively, and first and second diversity amplifiers configured to receive first and second diversity downlink signals, respectively.

In some aspects, the techniques described herein relate to a radio frequency front-end system further including first and second power amplifiers configured to provide first and second uplink signals, respectively.

In some aspects, the techniques described herein relate to a radio frequency front-end system wherein during the antenna calibration period, the first radio frequency switch is configured to simultaneously transmit a second sounding reference signal from the second power amplifier to the second antenna and receive a primary or a diversity downlink signal from the second antenna, the second sounding reference signal configured to determine a channel model for the second antenna.

In some aspects, the techniques described herein relate to a radio frequency front-end system wherein the first and second sounding reference signals are within the second frequency band.

In some aspects, the techniques described herein relate to a radio frequency front-end system wherein the first radio frequency switch includes a first antenna switch and a first plurality of radio frequency filters configured to provide frequency selective radio frequency paths between the first and second antennas and at least the one or more receive amplifiers.

In some aspects, the techniques described herein relate to a radio frequency front-end system wherein the first antenna switch and a first plurality of filters configured to provide frequency selective radio frequency paths between the first and second antennas and the first and second power amplifiers.

In some aspects, the techniques described herein relate to a radio frequency front-end system wherein the first radio frequency module further includes a first antenna-plexer connecting the first antenna and the first radio frequency switch, the first antenna-plexer configured to provide an external signal within a low frequency band to the first antenna while maintaining communication between the first antenna and the first radio frequency switch.

In some aspects, the techniques described herein relate to a radio frequency front-end system wherein the first radio frequency module further includes a second antenna-plexer connecting the second antenna and the first radio frequency switch, the second antenna-plexer configured to provide an external signal within an ultra-high frequency band to the second antenna while maintaining communication between the second antenna and the first radio frequency switch.

In some aspects, the techniques described herein relate to a radio frequency front-end system further including a second radio frequency module configured to establish multiple-input multiple-output communication via third and fourth antennas for transmitting third uplink signals over a third frequency band, and receiving downlink signals over the first and second frequency bands, the second radio frequency module including: a second radio frequency switch configured to: pass first downlink signals from at least one of the third and fourth antennas to a first receive amplifier; and pass second downlink signals from least one of the two antennas to a second receive amplifier; and the second radio frequency switch being configured, during the antenna calibration period, to simultaneously transmit a third sounding reference signal received from the first radio frequency module to the third antenna and receive a primary or a diversity downlink signal from the third antenna, the third sounding reference signal configured to determine a channel model for the third antenna.

In some aspects, the techniques described herein relate to a radio frequency front-end system wherein the first receive amplifier is configured to receive first downlink signals over the first frequency band and the second receive amplifier is configured to receive second downlink signals over the second frequency band.

In some aspects, the techniques described herein relate to a radio frequency front-end system wherein during the antenna calibration period, the second radio frequency switch is configured to simultaneously transmit a fourth sounding reference signal received from the first radio frequency module to the fourth antenna and receive a primary or a diversity downlink signal from the fourth antenna, the fourth sounding reference signal configured to determine a channel model for the fourth antenna.

In some aspects, the techniques described herein relate to a radio frequency front-end system wherein the third and fourth sounding reference signals are within the second frequency band.

In some aspects, the techniques described herein relate to a radio frequency front-end system wherein the second radio frequency switch includes a second antenna switch and a second plurality of radio frequency filters configured to provide frequency selective radio frequency paths between the third and fourth antennas and amplifiers of the second radio frequency module.

In some aspects, the techniques described herein relate to a radio frequency front-end system wherein the second radio frequency module receives the third and fourth sounding reference signals from the first radio frequency module through a signal trace electrically connecting the first and second radio frequency modules.

In some aspects, the techniques described herein relate to a radio frequency front-end system wherein the signal trace is connected to a first switch in the first radio frequency module, the first switch connecting the second power amplifier to the first radio frequency switch.

In some aspects, the techniques described herein relate to a radio frequency front-end system wherein the second radio frequency module is further configured to transmit EN-DC transmit signals.

In some aspects, the techniques described herein relate to a radio frequency front-end system wherein the second radio frequency module further includes a third power amplifier configured to provide the EN-DC transmit signal to the second radio frequency switch through a second switch.

In some aspects, the techniques described herein relate to a radio frequency front-end system wherein the signal trace is connected to the second switch.

In some aspects, the techniques described herein relate to a radio frequency front-end system wherein the second radio frequency module further includes a third antenna-plexer connecting the third antenna and the second antenna switch, the third antenna-plexer configured to provide an external signal within a low frequency band to the third antenna while maintaining communication between the third antenna and the second antenna switch.

In some aspects, the techniques described herein relate to a radio frequency front-end system wherein the second radio frequency module further includes a fourth antenna-plexer connecting the fourth antenna and the second antenna switch, the fourth antenna-plexer configured to provide an external signal within an ultra-high frequency band to the fourth antenna while maintaining communication between the fourth antenna and the second antenna switch.

In some aspects, the techniques described herein relate to a radio frequency front-end system above wherein the first frequency band includes a mid-frequency band and the second frequency band includes a high-frequency band.

In some aspects, the techniques described herein relate to a radio frequency front-end system wherein the mid-frequency band includes B25 and high-frequency band includes n41.

In some aspects, the techniques described herein relate to a mobile device including: first and second antennas; and a first radio frequency module configured to transmit first uplink signals over a first frequency band and second uplink signals over a second frequency band, and receive primary and diversity downlink signals over the first and second frequency bands, the first radio frequency module including a first radio frequency switch configured to: pass first primary downlink signals and first diversity downlink signals within the first frequency band from at least one of a first antenna and a second antenna to one or more receive amplifiers; pass second primary downlink signals and second diversity downlink signals within the second frequency band from at least one of the first and second antennas to the one or more receive amplifiers; and during an antenna calibration period, simultaneously transmit a first sounding reference signal to the first antenna and pass a primary or a diversity downlink signal from the first antenna to the one or more receive amplifiers.

In some aspects, the techniques described herein relate to a radio frequency front-end system including: a first radio frequency front-end module including a first transmit amplifier configured to output first uplink signals over a first frequency band, a second transmit amplifier configured to output second uplink signals over a second frequency band, a first receive amplifier configured to receive primary downlink signals over the first frequency band, a second receive amplifier configured to receive diversity downlink signals over the first frequency band, and first radio frequency switch configured, during an antenna calibration period, to simultaneously: pass the second uplink signals corresponding to one or more sounding reference signal symbols to a first antenna, pass the primary downlink signals from the first antenna to the first receive amplifier, and pass the diversity downlink signals from a second antenna to the second receive amplifier; and a second radio frequency front-end module coupled to the first radio frequency front-end module to receive the second uplink signals, and including: a third receive amplifier configured to receive third downlink signals over the first frequency band, a fourth receive amplifier configured to receive fourth downlink signals over the first frequency band; and a second radio frequency switch configured, during another antenna calibration period, to simultaneously: pass the second uplink signals corresponding to one or more second sounding reference signal symbols to a third antenna, pass the third downlink signals from the third antenna to the third receive amplifier, and pass the fourth downlink signals from a fourth antenna to the fourth receive amplifier.

In some aspects, the techniques described herein relate to a radio frequency front-end system including: a first radio frequency module including a first radio frequency switch configured to: pass first primary downlink signals and first diversity downlink signals over a first frequency band from at least one of a first antenna and a second antenna to one or more first receive amplifiers, and during a first antenna calibration period, simultaneously transmit a first sounding reference signal over the first frequency band to the first antenna and pass the first primary downlink signal or the first diversity downlink signal from the first antenna to the one or more first receive amplifiers; and a second radio frequency module electrically coupled to the first radio frequency module and including a second radio frequency switch configured to: pass first downlink signals over the first frequency band from at least one of a third antenna and fourth antennas to one or more second receive amplifiers, and during a second antenna calibration period, simultaneously transmit a second sounding reference signal received from the first radio frequency module over the first frequency band to the third antenna, and pass the first downlink signals from the third antenna to the one or more second receive amplifiers.

In some aspects, the techniques described herein relate to a radio frequency front-end system the first and second sounding reference signal are configured to determine channel models for the first and third antennas, respectively.

In some aspects, the techniques described herein relate to a radio frequency front-end system wherein the first radio frequency switch passes the first sounding reference signal to the first antenna without interrupting an anchor link established based on the first antenna.

In some aspects, the techniques described herein relate to a radio frequency front-end system wherein the first radio frequency switch includes a first antenna switch and a first plurality of radio frequency filters configured to provide frequency selective radio frequency paths between the first and second antennas and at least the one or more first receive amplifiers.

In some aspects, the techniques described herein relate to a radio frequency front-end system wherein the second radio frequency switch includes a second antenna switch and a second plurality of radio frequency filters configured to provide frequency selective radio frequency paths between the third and fourth antennas and at least the one or more second receive amplifiers.

In some aspects, the techniques described herein relate to a radio frequency front-end system wherein the first radio frequency module further includes a first antenna-plexer connecting the first antenna and the first radio frequency switch, the first antenna-plexer including a first portion configured to provide a low frequency band signal to the first antenna and a second portion connected between the first antenna and the first radio frequency switch.

In some aspects, the techniques described herein relate to a radio frequency front-end system wherein the first radio frequency module further includes a second antenna-plexer connecting the second antenna and the first radio frequency switch, the second antenna-plexer including a first portion configured to provide an ultra-high frequency band signal to the second antenna and a second portion connected between the second antenna and the first radio frequency switch.

In some aspects, the techniques described herein relate to a radio frequency front-end system wherein the second radio frequency module further includes a third antenna-plexer connecting the third antenna and the second antenna switch, the third antenna-plexer including a first portion configured to provide a low frequency band signal to the third antenna and a second portion connected between the third antenna and the second antenna switch.

In some aspects, the techniques described herein relate to a radio frequency front-end system wherein the second radio frequency module further includes a fourth antenna-plexer connecting the fourth antenna and the second antenna switch, the fourth antenna-plexer including a first portion configured to provide an ultra-high frequency band signal to the fourth antenna and a second portion connected between the fourth antenna and the second antenna switch.

In some aspects, the techniques described herein relate to a radio frequency front-end system wherein the second radio frequency module is further configured to establish multi-input multi-output communication via the third antenna and the fourth antenna for transmitting third uplink signals over a third frequency band and receiving the first downlink signals and second downlink signals over a second frequency band.

In some aspects, the techniques described herein relate to a radio frequency front-end system wherein the third uplink signals include EN-DC transmit signals.

In some aspects, the techniques described herein relate to a radio frequency front-end system, wherein the first radio frequency switch is further configured: during a third antenna calibration period, simultaneously transmit a third sounding reference signal to the second antenna and pass the first primary downlink signal or the first diversity downlink signal from the second antenna to the one or more first receive amplifiers, the third sounding reference signal usable for determining a channel model for the second antenna.

In some aspects, the techniques described herein relate to a radio frequency front-end system, wherein the first radio frequency module is further configured to: transmit second uplink signals over a second frequency band, receive second primary downlink signals over the second frequency band, and receive second diversity downlink signals over the second frequency band, and the first radio frequency switch is further configured to pass the second primary downlink signals and the second diversity downlink signals from at least one of the first antenna and the second antenna to the one or more first receive amplifiers.

In some aspects, the techniques described herein relate to a radio frequency front-end system wherein the one or more first receive amplifiers: first and second primary amplifiers configured to receive first and second primary downlink signals, respectively, and first and second diversity amplifiers configured to receive first and second diversity downlink signals, respectively.

In some aspects, the techniques described herein relate to a radio frequency front-end system further including first and second power amplifiers configured to provide first and second uplink signals, respectively.

In some aspects, the techniques described herein relate to a radio frequency front-end system wherein the first and second reference sounding signals include the second uplink signals provided by the second amplifier during the first and second antenna calibration periods, respectively.

In some aspects, the techniques described herein relate to a radio frequency front-end system wherein the second radio frequency module is configured to establish multi-input and multi-output communication via the third antenna and the fourth antenna for transmitting third uplink signals over a third frequency band, and receiving the first downlink signals and second downlink signals over the first and second frequency bands, the one or more second receive amplifiers including: a first plurality of amplifiers configured to receive first downlink signals over the first frequency band, and a second plurality of amplifiers configured to receive second downlink signals over the second frequency band.

In some aspects, the techniques described herein relate to a radio frequency front-end system further including a third power amplifier configured to provide the third uplink signals.

In some aspects, the techniques described herein relate to a radio frequency front-end system further including a signal trace electrically connecting the first and second radio frequency modules wherein the second radio frequency module receives the second sounding reference signal from the first radio frequency module through the signal trace.

In some aspects, the techniques described herein relate to a radio frequency front-end system wherein the signal trace electrically connects a first switch in the first radio frequency module to a second switch in the second radio frequency module, the first switch connecting a power amplifier of the first radio frequency module to the first radio frequency switch and the second switch connecting a power amplifier of the second radio frequency module to the second radio frequency switch.

In some aspects, the techniques described herein relate to a radio frequency front-end system wherein the first frequency band includes a mid-frequency band and the second frequency band includes a high-frequency band.

In some aspects, the techniques described herein relate to a radio frequency front-end system wherein the mid-frequency band includes B25 and high-frequency band includes n41.

In some aspects, the techniques described herein relate to a mobile device including the radio frequency front-end system.

In some aspects, the techniques described herein relate to a mobile device including: first, second, third, and fourth antennas; a first radio frequency module including a first radio frequency switch configured to: pass first primary downlink signals and first diversity downlink signals over a first frequency band from at least one of the first antenna and the second antenna to one or more receive first amplifiers, and during a first antenna calibration period, simultaneously transmit a first sounding reference signal over the first frequency band to the first antenna and pass a first primary downlink signal or a first diversity downlink signal from the first antenna to the one or more first receive amplifiers; and a second radio frequency module electrically coupled to the first radio frequency module and including a second radio frequency switch configured to: pass first downlink signals over the first frequency band from at least one of the third antenna and the fourth antenna to one or more second receive amplifiers, and during a second antenna calibration period, simultaneously transmit a second sounding reference signal received from the first radio frequency module to the third antenna, and pass first downlink signals from the third antenna to the one or more second receive amplifiers.

### BRIEF DESCRIPTION OF THE DRAWINGS

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is a schematic diagram of one example of an uplink channel using MIMO communications.

FIG. 3C is a schematic diagram of another example of an uplink channel using MIMO communications.

FIG. 4 is a schematic diagram of an example dual connectivity network topology.

FIG. 5 is a schematic diagram of an embodiment of a radio frequency (RF) module.

FIG. 6 is a schematic diagram of one embodiment of a front-end system.

FIG. 7 is a schematic diagram of an embodiment of a radio frequency (RF) font-end RF system having separate primary and diversity receiver modules.

FIG. 8 is a schematic diagram of an embodiment of a radio frequency (RF) font-end system having combined primary and diversity receiver circuitry in a single module.

FIG. 9 is a schematic diagram of an embodiment of a radio frequency (RF) font-end system including (RF) font-end system shown in FIG. 9 and a multi-input and multi-output (MIMO) communication module.

FIG. 10A is a schematic diagram of an example embodiment of the font-end system shown in FIG. 9.

FIG. 10B is a schematic diagram of an example embodiment of the (MIMO) communication module shown in FIG. 9.

FIG. 11 is a schematic diagram of one embodiment of a mobile phone.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High-Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

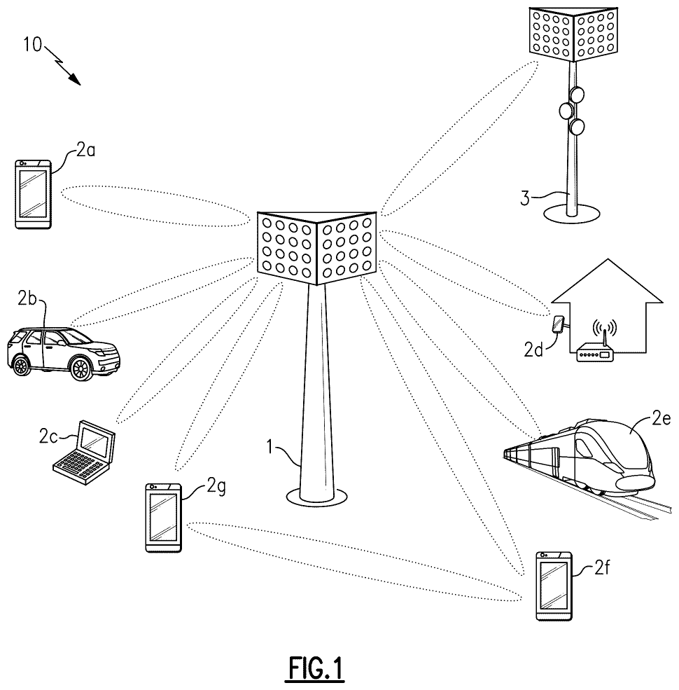

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul.

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

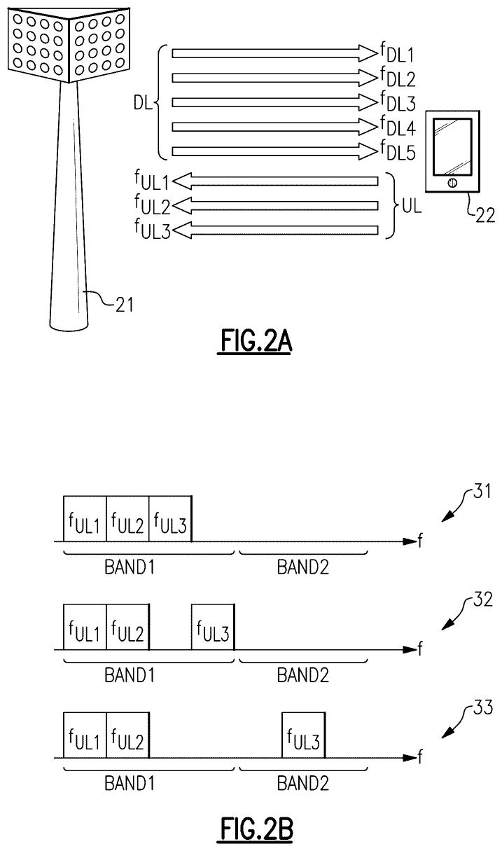

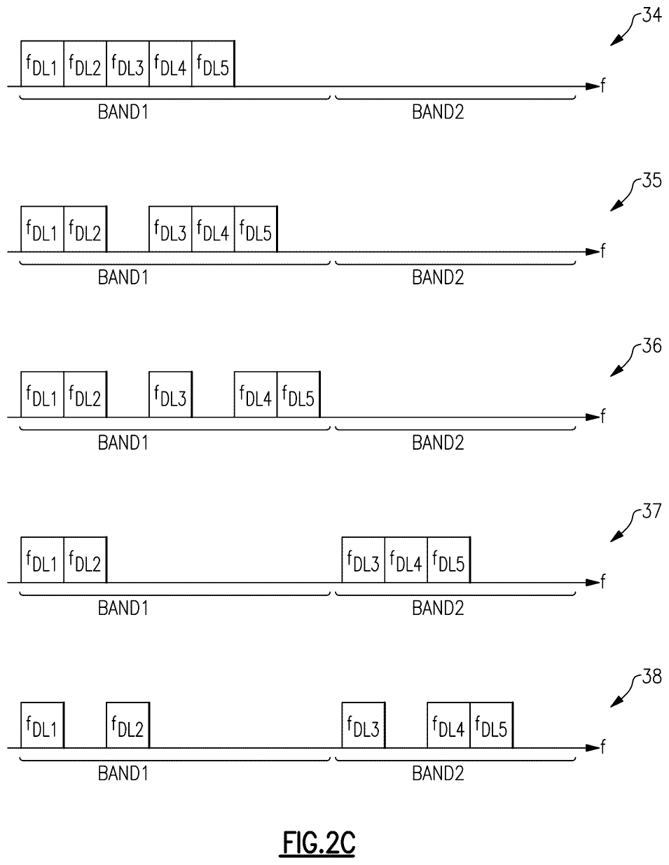

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and second cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

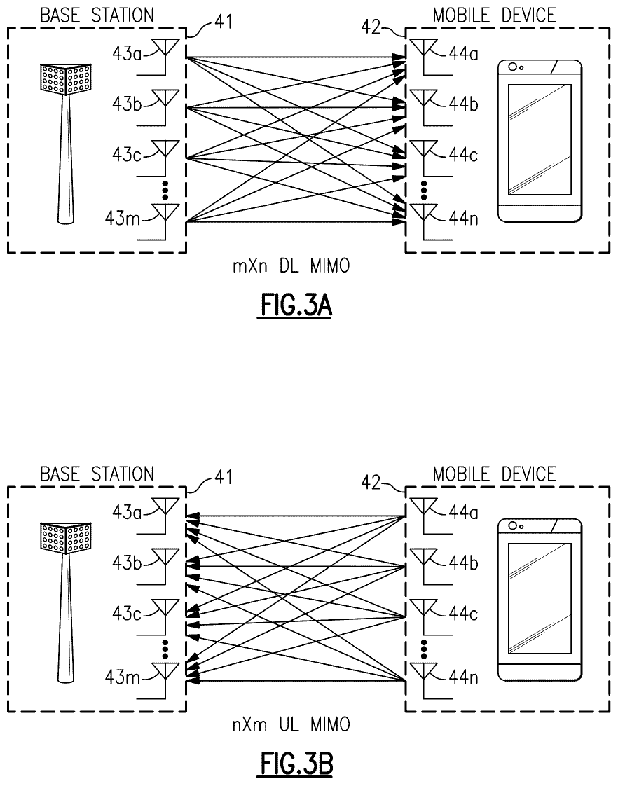

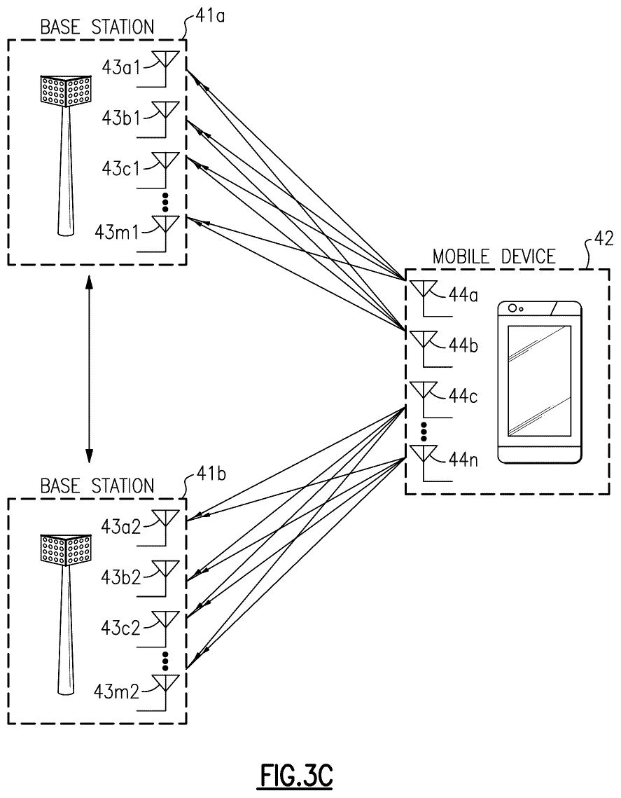

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additionally a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

In some implementations, to enable MIMO operation (e.g., massive MIMO operation), Sounding Reference Signals (SRSs) comprising known symbols are transmitted through each of the antennas of the UE (e.g., DL or shared antennas) in a known sequence and via UL paths established by antenna port switching. The basestation (e.g., gNodeB or gNB) may receive these known symbols and use them to calculate an accurate transfer function to model the RF channels, e.g., in terms of phasing, reflections, and fades across bandwidth. The resulting channel models may be used to establish MIMO (e.g., Massive MIMO) connection from the corresponding basestation to each UE antenna. For example, the channel model may be used for beamforming, optimizing coherence summation at an antenna of the UE, and, in some cases, zero cancel for the other surrounding UEs to reduce interference.

In some implementations, it can be advantageous to send the SRS in TDD because in TDD the UL channel and the DL channel are established based on the same carrier frequency and thereby experience the same environment and can use the same channel model/RF. In contrast, if the SRS is sent in FDD the Tx and Rx carrier frequencies will be different and the UE needs to perform intensive calculations and send the resulting channel information back to the base station (e.g., gNB) so that the basestation can use the information for establishing MIMO connection for a DL channel separate from the UL channel. The overhead, extra data exchange, and delay associated with this process adversely impacts the performance of the communication link.

In some cases, an interworking between an LTE and a 5G NR base stations can be established to allow a mobile device to exchange data between the 5G NR base station along with simultaneous connection with the LTE base station to leverage benefits of both LTE and 5G connectivity simultaneously. In some cases, such dual connectivity configuration may be referred to as Evolved-Universal Terrestrial Radio Access-New Radio, E-UTRA NR Dual connectivity or EN-DC. In a dual connectivity mode, in some examples, UE may be simultaneously connected to LTE and 5G NR or to LTE for control plane and a 5G NR for user plane. In some implementations, in an EN-DC architecture, a UE can establish connections to an eNodeB that acts as a master node and to a gNodeB that acts as a secondary node.

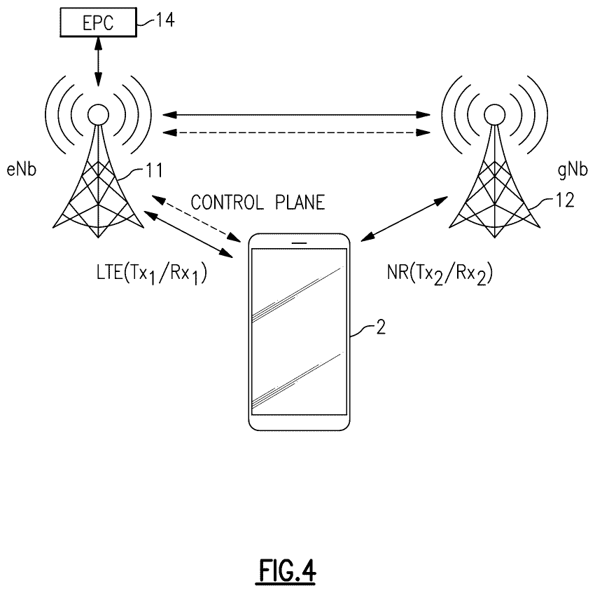

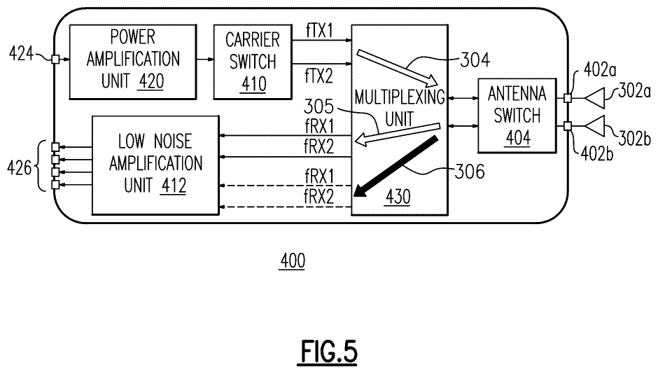

FIG. 4 is a schematic diagram of an example dual connectivity network topology. This architecture can leverage LTE legacy coverage to ensure continuity of service delivery and the progressive rollout of 5G cells. A UE 2 can simultaneously transmit dual uplink LTE and NR carrier. The UE 2 can transmit an uplink LTE carrier Tx1 to the eNB 11 while transmitting an uplink NR carrier Tx2 to the gNB 12 to implement dual connectivity. Any suitable combination of uplink carriers Tx1, Tx2 and/or downlink carriers Rx1, Rx2 can be concurrently transmitted via wireless links in the example network topology of FIG. 1. The eNB 11 can provide a connection with a core network, such as an Evolved Packet Core (EPC) 14. The gNB 12 can communicate with the core network via the eNB 11. Control plane data can be wireless communicated between the UE 2 and eNB 11. The eNB 11 can also communicate control plane data with the gNB 12. Control plane data can propagate along the paths of the dashed lines in FIG. 4. The solid lines in FIG. 4 are for data plane paths.

In the example dual connectivity topology of FIG. 4, any suitable combinations of standardized bands and radio access technologies (e.g., FDD, TDD, SUL, SDL) can be wirelessly transmitted and received. This can present technical challenges related to having multiple separate radios and bands functioning in the UE 2. With a TDD LTE anchor point, network operation may be synchronous, in which case the operating modes can be constrained to Tx1/Tx2 and Rx1/Rx2, or asynchronous which can involve Tx1/Tx2, Tx1/Rx2, Rx1/Tx2, Rx1/Rx2. When the LTE anchor is a frequency division duplex (FDD) carrier, the TDD/FDD inter-band operation can involve simultaneous Tx1/Rx1/Tx2 and Tx1/Rx1/Rx2.

As discussed above, EN-DC can involve both 4G and 5G carriers being simultaneously transmitted from a UE. Transmitting both 4G and 5G carriers in a UE, such as a phone, typically involves two power amplifiers (PAs) being active at the same time. Traditionally, having two power amplifiers active simultaneously would involve the placement of one or more additional power amplifiers specifically suited for EN-DC operation. Additional board space and expense is incurred when designing to support such EN-DC/NSA operation.

### Example RF Front-End Architecture

Features in 5G, such as sounding reference signal (SRS) antenna port switching can necessitate additional connectivity of the transmitter (or the transceiver) to available downlink capable antennas in UE. Thus, even though such antennas are used for downlink (receiving signals) for regular UE communications, such feature support necessitates access of the UE's transmitter to the antennas.

Moreover, the geographical positioning of the RF modules within the UE (for example, to place an RF module close to a particular antenna) can result in certain RF modules being far from the transceiver and/or other RF modules. The cable connections and routes between the transmitter and remote antennas and/or other RF modules can often result in losses that degrade performance, raise coupling/isolation challenges, and/or introduce expensive cross-UE cables and corresponding connections. Furthermore, such connection overhead can result in significant loss arising from both the cabling itself as well as from multiple cascaded series switches included to provide appropriate connectivity.

FIG. 5 is a schematic diagram of an example RF front-end system 400 configured for CA-based wireless communication according to an embodiment. In some cases, the RF front-end system 400 may be configured to establish an uplink (UL) channel using two or more uplink carrier frequencies, and two or more down link (DL) channels using two or more downlink carrier frequencies. In some cases, a CA uplink channel 304 may comprise multiple RF transmit paths. In some cases, each CA downlink channel 305, 306 may comprise multiple RF receive paths. In some wireless communication links, user demand for downlink capacity can be higher than that of uplink capacity (e.g., for multimedia content streaming). As such in some cases, the RF front-end system 400 may be configured to establish at least two downlink channels functioning in parallel: a main downlink channel 305 and a diversity downlink channel 306. In some embodiments, the main downlink channel 305 and the diversity downlink channel 306 may be established in different modules of the RF front-end system 400. In other embodiments, the main downlink channel 305 and the diversity downlink channel 306 are integrated in the same RF front end module, such as will be described in connection with the embodiments of FIGS. 8, 9, and 10A.

In some implementations, within the RF front-end system 400, the uplink channel 304 comprises a separate transmit path for each uplink carrier frequency and each downlink channel 305 or 306 comprises a separate receive path for each downlink carrier frequency. In one embodiment, the RF front-end system 400 may comprise a power amplification unit 420 (e.g., a transistor-based power amplifier), a carrier switch 410, a multiplexing unit 430, an antenna switch 404, two antenna ports 402a, 402b, and a low noise amplification unit 412. In some examples, a first antenna port 402a can be electrically connected to a first antenna 302a and a second antenna port 402b can be connected to a second antenna 302b. In some embodiments, the multiplexing unit 430 can include at least two input ports connected to the carrier switch 410, at least four output ports connected to the low noise amplification unit, and at least two transmit/receive (TR) ports connected to the antenna switch 404. In some examples, the power amplification unit 420 receives a transmit signal via a transmit signal port 424, amplifies the received transmit signal and provides the amplified transmit signal to the multiplexing unit 430 via the carrier switch 410. The carrier switch 410 is configured to provide the amplified transmit signal to the multiplexing unit 430 based on an uplink carrier frequency of the amplified signal. For example, the carrier switch 410 may provide the amplified signal to an input port of the multiplexing unit 430 may pass the signals having frequencies within a particular bandwidth around the uplink carrier frequency and attenuate the signals having frequencies outside the bandwidth (e.g., by more than 20 dB, 30 dB, 40 dB, or 60 dB). The multiplexing unit 430 may be configured to provide the amplified signal to the antenna port 402a or 402b from one of its transmit/receive (TR) ports and via the antenna switch 404. The multiplexing unit 430 may be further configured to provide a receive signal received from the antenna port 402a or 402b, via one of its TR ports, to the low noise amplification unit 412. In some examples, the antenna switch 404 may direct receive signals to one or more TR ports of the multiplexing unit 430 configured to pass signals having frequencies within a particular bandwidth around a downlink carrier frequency of the receive signal and attenuate the signals having frequencies outside the bandwidth (e.g., by more than 20 dB, 30 dB, 40 dB, or 60 dB). In some examples, transmit signals having different uplink carrier frequencies (e.g., fTX1 and fTX2) may be provided to the same or different antenna ports 402a, 402b via a different transmit path for each uplink carrier frequency. In some embodiments, a receive signal having a downlink carrier frequency may be received from both antennas 302a and 302b via both antenna ports 402a, 402b and pass through the multiplexing unit 430 via two distinct paths: a main receive path and a diversity receive path. As such, in the example shown, receive signals having two downlink frequencies fRX1 and fRX2, may be directed from both antennas ports 402a, 402b, to the low noise amplification unit 412 via four distinct receive paths: two main receive paths and two diversity receive paths resulting in an enhanced downlink speed compared to the uplink speed.

In some implementations, the multiplexing unit 430 may be configured to provide an uplink channel 304 comprising two frequency selective RF transmit paths for each of the two uplink carrier frequencies (e.g., fTX1 and fTX2), a main downlink channel 305 comprising a frequency selective RF receive path for each of two down link carrier frequency (e.g., fRX1 and fRX2), and a diversity downlink channel 306 comprising a frequency selective RF receive path for each of the two down link carrier frequencies (e.g., fRX1 and fRX2).

In some embodiments, a frequency selective RF path (e.g., transmit or receive path) may comprise a low loss RF path that is configured to allow low loss RF transmission at frequencies within a passband around a carrier frequency (e.g., a carrier frequency of a carrier aggregated wireless communication link) while attenuating signals having frequencies outside of the passband (e.g., other carrier frequencies of the carrier aggregated wireless communication link). In some examples, a frequency selective RF path provides the minimal insertion loss within the corresponding passband and attenuates the noise outside of its passband to the desired level.

In some embodiments, a frequency selective RF path may comprise at least one bandpass RF filter configured to provide, at least partially, the frequency selectivity of the path. In some cases, the bandpass filter may attenuate signals having frequencies within its passband by less than 2 dB, less than 1 dB, less than 0.5 dB or smaller values, and attenuate signals having frequencies outside of its passband by than 20 dB, more than 30 dB, more than 40 dB, more than 50 dB, more than 60 dB, or larger values. In various implementations, the passband of an RF path within the multiplexing unit 430 or the passband of the corresponding band pass filter can be from 1 MHZ to 10 MHZ, from 10 MHz to 100 MHz, from 100 MHz to 500 MHZ or any ranges formed by these values.

In some implementations, a carrier aggregated wireless communication link may be established using four carrier frequencies: two carrier frequencies for the uplink channel (e.g., uplink channel 304) and two carrier frequencies for each downlink channel (e.g., the main down link channel 305 and the diversity downlink channel 306). In some cases, one of the two uplink carrier frequencies and one of the two downlink carrier frequencies can be within a low band (LB) and the other of the two uplink carrier frequencies and the other of the two downlink carrier frequencies within a high band (HB). In various implementations, the HB and LB can be associated with 4G long-term evolution (LTE) technology or 5G New Radio (NR) technology. In some cases, one of the two uplink carrier frequencies and one of the two downlink carrier frequencies can be within the band n25 and the other of the two uplink carrier frequencies and the other of the two downlink carrier frequencies within band n41.

In some cases, a frequency selective RF path and/or the corresponding bandpass filter may be configured to transmit signals having one of the four carrier frequencies and attenuate or reject the signals having at least one of the other carrier frequencies. In some cases, the spectrum of a signal having a carrier frequency may comprise the carrier frequency and frequency components within a bandwidth around the carrier frequency.

In some cases, the number of uplink carrier frequencies can be equal to (symmetric CA) or different (asymmetric CA) from a number of downlink carrier frequencies. Accordingly, a number of transmit paths within an uplink channel can be equal to or different from a number of receive paths within a downlink channel (e.g., main or diversity receive channel).

In various implementations, the multiplexing unit 430 may comprise one or more frequency multiplexers (e.g., frequency duplexers or triplexers) configured to support the low loss transmit and receive RF paths (e.g., main and diversity receive paths). The frequency multiplexers (also referred to as multiplexers) may be configured to provide the transmit and receive paths between the input ports and the RT ports and receive paths between RT ports and the output ports of the multiplexing unit 430. In some embodiments, separate multiplexers may be used to establish the transmit channel and the diversity receive channel within the multiplexing unit 430. In some embodiments, such as the embodiments disclosed herein, at least one multiplexer may be shared between an uplink channel (e.g., uplink channel 304) and a diversity downlink channel (e.g., diversity downlink channel 306). Advantageously, in some such embodiments (where a multiplexer is shared between the uplink channel and the diversity downlink channel), the multiplexers of the multiplexing unit 430 may not load each other, and the channels can be implemented using a smaller number of multiplexers. As a result, in these embodiments, the insertion loss of each channel may decrease, and the overall sensitivity and power added efficiency of the RF front-end system 400 may increase.

In some cases, the multiplexer may comprise one or more bandpass frequency filters (also referred to as filter portions) each configured to receive an input signal from a different simplex port of a plurality of simplex ports and an interconnection that combines the filtered signals transmitted through the individual bandpass filters and outputs the resulting combined signal via a multiplex port. In some cases, when the multiplexer is used as a demultiplexer a signal received via the multiplex port is distributed among the bandpass filters and each filtered signal transmitted through the respective bandpass frequency filter is output from a different simplex port.

In some embodiments, various filter designs may be used in a multiplexer/demultiplexer usable in communication systems and devices functioning based on CA scheme. In some embodiments, a filter of the multiplexer/demultiplexer can be a bandpass filter. In some cases, the bandpass filter can be a resonant filter comprising one or more RF resonators or configured to provide a frequency passband having a bandwidth around the corresponding carrier frequency. In some cases, the bandwidth of the filter can be inversely proportional to a number of resonators and the output band rejection (attenuation) and in band loss of the filter can be directly proportional to a number of resonators. In some cases, the RF resonators used in the bandpass filter may comprise planar conductive resonators, bulk dielectric resonators, surface acoustic wave (SAW) resonators, or bulk acoustic wave (BAW) resonators.

In some cases, a multiplexer may be fabricated (e.g., monolithically) on a single chip. For example, a multiplexer may comprise SAW filters formed on a common substrate. In some cases, two multiplexers may be fabricated on a common substrate but can be electrically isolated. In some cases, the RF isolation between two individual multiplexers fabricated on the same substrates can be greater than 10 dB, greater than 15 dB, greater than 20 dB or greater values.

In some cases, multiplex ports of two or more multiplexers may be connected to a single port RT port of the multiplexing unit 430. In some such cases, the impedance of the multiplex port for the out of band frequencies of the corresponding multiplexers may decrease compared to that of a single multiplexer and/or compared to an open impedance (e.g., due to loading effect). In some cases, the impedance of the multiplex port for the out of band frequencies of the corresponding multiplexers may decrease proportional to the magnitude of out-of-band gamma (the reflection or S11 coefficient) of the individual multiplexers connected to the corresponding multiplex port. As such it may be advantageous to design the multiplexing unit 430 such that the multiplexers and/or filters are electrically isolated and do not load each other.

Antenna Puncturing Arising from Sounding Reference Signaling (SRS)

As described above with respect to FIG. 4, in some communication systems the UE may simultaneously communicate using 4G and 5G carriers and using corresponding technologies. In some implementations, to facilitate such operation, a 5G radio head can be added to a 4G tower or basestation. In some such implementations the 4G (E-UTRA) and 5G (NR) links may operate independently due to limitations on the 4G link, e.g., to support the required 5G channelization. This independent operation may require Uplink (UL) and Downlink (DL) for both 4G and 5G bands, so-called “Evolved-Universal Terrestrial Radio Access New Radio” referred to as E-UTRA-NR Dual Connectivity or EN-DC. In EN-DC mode, the UE may be simultaneously connected via LTE and NR or use LTE for control plane and NR for user plane. However, embodiments are not so limited and other combinations are possible. In some cases, in an EN-DC architecture, a UE may establish connection to a first base station (e.g., eNodeB) that acts as a master node and to a second basestation (gNodeB) that acts as a secondary node.

Such simultaneous operation may pose certain technical challenges including but not limited to generation of intermodulation products resulting in intermodulation distortion and interruption of 4G down links by the required transmission of Sounding Reference Signals through shared antennas of the UE.

For example, the Tx1 (e.g., a 4G signal such as a B25) and Tx2 (e.g., a 5G signal such as an n41 signal) may be mixed due to nonlinearities of various blocks in the RF front-end (RF-FE) and generate an intermodulation product having a frequency close to a DL carrier and thereby degrading the performance of the corresponding DL signals (e.g., B25 receive signals).

As described above, in various implementations, usage of MIMO (e.g., massive MIMO) technology can significantly increase the bandwidth and performance of the communication between a basestation and UE, e.g., by improving SNR and thereby increasing network capacity (e.g., by as much as 8×), average sector throughput (e.g., as much as 6×), UL coverage gain (by as much as 4 dB), and call edge throughput (by as much as 4×) compared to technologies that do not use MIMO or massive MIMO (e.g., in a gNB base station). However, to enable MIMO operation (e.g., massive MIMO operation), Sounding Reference Signals (SRSs) may need to be transmitted through each of the antennas of the UE (e.g., DL or shared antennas) via UL paths established by antenna port switching (e.g., such SRS transmission can include transmitting a known reference signal on each antenna for purposes of channel estimation and modeling). When EN-DC is supported within a band group, e.g., a common group of bands within a specific frequency range (e.g., 1410-2690 MHz corresponding to MB band group), transmission of SRS by antenna port switching may temporarily interrupt the usage of one of the DL antennas. For example, when an SRS within n41 band is transmitted via an UL, the corresponding UL signal path may be configured (e.g., by a switch), to “take-over” a first antenna through which a midband (MB) anchor (e.g., B25) might be transmitting and receiving signals. As a result, the MB anchor Tx and Rx may be interrupted during the SRS transmission resulting in a broken anchor, risk of dropping the entire connection, or at least significant drop in throughput for the MB anchor. This issue is termed “puncturing” of the anchor (MB in this case).

Some communication systems simultaneously communicate over multiple frequency bands. For example, a 5G radio can simultaneously communicate both a NR TDD band and a 4G and/or 5G NR band during carrier aggregation (CA) or EN-DC operation. The 4G/5G NR band can be TDD or FDD. In certain applications, the two frequency bands (for example, a first band that is NR TDD a second band that is LTE/NR FDD or TDD) share antenna feed paths in the front-end system without frequency selectivity by an antenna-plexer. Some of these operating scenarios also are specified to operate with simultaneous transmission of the first band and reception of the second band. One such example is using n41 and B25 CA or EN-DC. In such operating scenarios, SRS may be performed for the first frequency band in time domain (e.g., in a NR TX TDD modality). Such SRS signaling can interrupt (puncture) the second frequency band DL RX signal by taking over the shared antenna for purposes of an SRS transmission. For example, a power amplifier for the NR TX TDD frequency band can be connected through a front-end switch (e.g., an antenna switch module or ASM) for a duration of time to transmit an SRS. During this period (which may be as short as 1 uplink symbol in some cases), downlink connectivity for the second frequency band can be lost. The effect of this puncturing on the second band's downlink throughput can be substantial and may lead to SNR reduction of varying degrees, depending on the downlink signal type. Here, SNR reduction is defined as the amount of increased SNR required to attain a given throughput (e.g., 95%), compared to a throughput during unpunctured operation.

Some of RF front architectures described below can prevent puncturing in certain mobile systems by enabling switch combining RF paths to multiple antennas, e.g., for SRS transmission without interrupting DL communication via one or more diversity downlink channels.

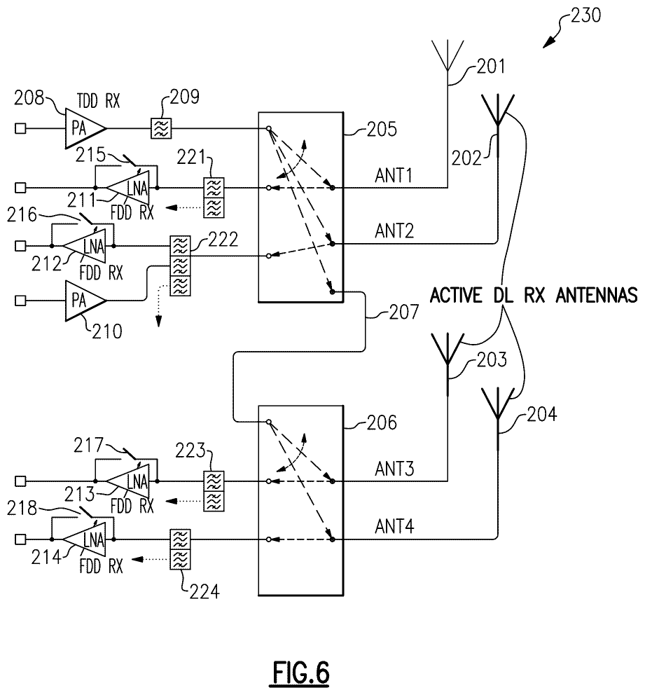

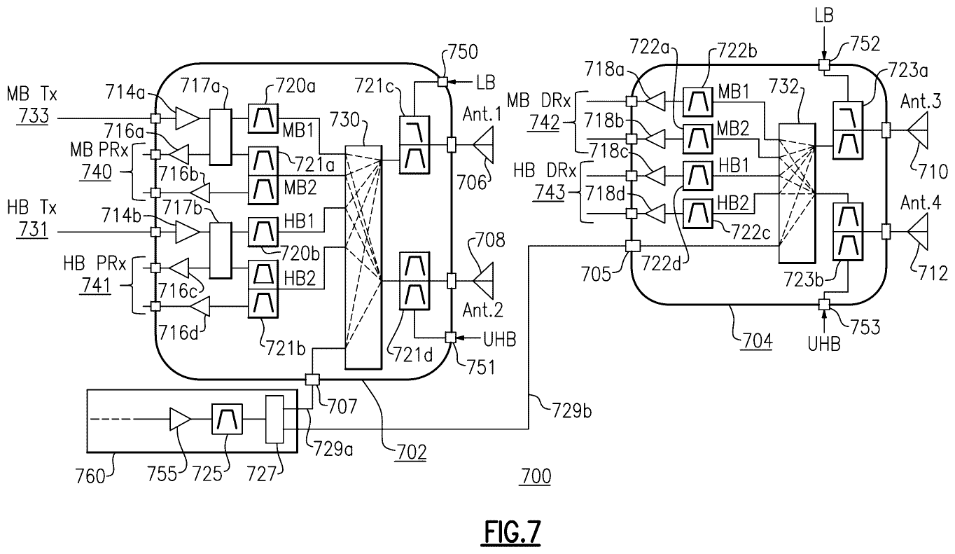

FIG. 6 is a schematic diagram of one embodiment of a front-end system 230. As shown in FIG. 6, the front-end system 230 is connected to a first antenna 201, a second antenna 202, a third antenna 203, and a fourth antenna 204. Although not shown in FIG. 6, the front-end system 230 can be connected to a radio of a mobile device. Such a radio can include a baseband processor and a modem/transceiver.

In the illustrated embodiment, the front-end system 230 includes a first antenna switch 205, a second antenna switch 206, an antenna switch interconnection path 207 (e.g., a signal trace), a power amplifier 208 for a first frequency band (TDD TX, in this example), a transmit filter 209 for the first frequency band, a first low noise amplifier (LNA) 211 for a second frequency band (FDD RX, in this example), a second LNA 212 for the second frequency band, a third LNA 213 for the second frequency band, a fourth LNA 214 for the second frequency band, a first bypass switch 215 for the first LNA 211, a second bypass switch 216 for the second LNA 212, a third bypass switch 217 for the third LNA 213, a fourth bypass switch 218 for the fourth LNA 214, a first antenna-plexer 221, a second antenna-plexer 222, a third antenna-plexer 223, and a fourth antenna-plexer 224. In some implementations, the first frequency band can be n41 and the second frequency band can be n25.

Absent a mitigation technique, the NR TDD TX SRS outputted by the first power amplifier 208 to the antennas 201-204 (for example, for fast hopping SRS) can give rise to antenna puncturing for the second frequency band. Thus, the first frequency band SRS may interrupt the second frequency band DL signal and take over an antenna for SRS transmission when an SRS transmission is scheduled by the gNodeB/eNodeB/serving cell.

In a first example, the second frequency band is in CA with the first frequency band (which transmits SRSs) or in EN-DC operation. In a second example, the second frequency band is FDD and thus assumed to be nominally operating DL as well as UL at any time. In a third example, the second frequency band is TDD and is not synchronized with the first frequency band such that UL for the first frequency band overlaps with DL for the second frequency band.

Such antenna puncturing can cause loss of DL throughput (and consequently data rate) in the second frequency band. The antenna puncturing degradation can lead to a loss of throughput that is dependent on the MCS and rank of the DL gNodeB/eNodeB transmission of the second frequency band as well as propagation channel conditions. Furthermore, the loss of throughput may be excessively disproportionate to the number of antennas interrupted (punctured) and the puncturing-duty cycle of that antenna or the whole system of antennas.

Apparatus and methods for mitigating antenna puncturing, e.g., puncturing arising from SRS, are disclosed. Some of the RF front-end architectures described herein can prevent puncturing in certain mobile systems by increased module integration and by enabling switch combining RF paths to multiple antennas, e.g., for SRS transmission, without interrupting DL communication via one or more downlink channels, e.g., one or more diversity downlink channels.

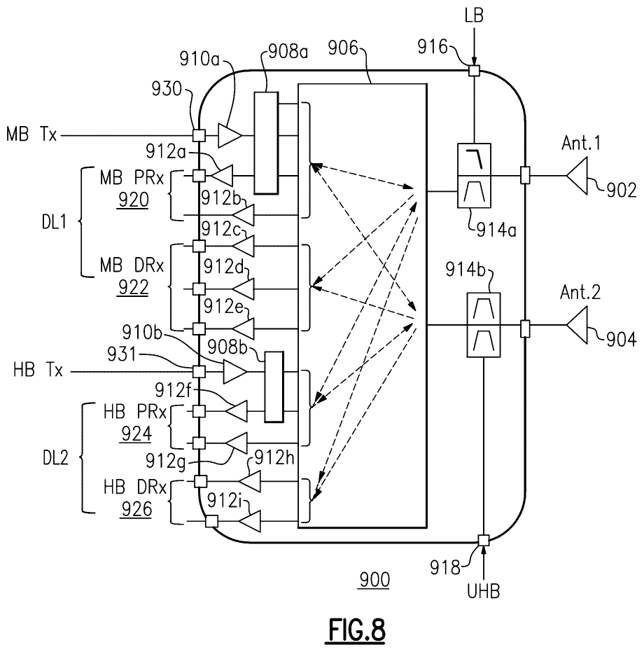

FIG. 7 is a schematic diagram of an embodiment of a radio frequency (RF) font-end system 700 (e.g., the RF front end of a UE) having separate primary and diversity receiver modules. In this embodiment, the front-end system 700 includes two separate modules, a first module 702 (also referred to as primary module) for wireless communication via primary carrier frequencies in two different frequency bands and a second module 704 (also referred to as diversity module) to support diversity channels for DL communication for the two frequency bands. In some implementations, the primary carrier frequencies may comprise two mid band (MB) carrier frequencies (MB1 and MB2), and two high band (HB) carrier frequencies. In some implementations, the two modules can be located at two different locations within the UE (e.g., at different sides, corners, or edges of an enclosure). In some such implementations, the location (e.g., relative location) of the first and second modules 702, 704, e.g., the relative location on a phone board of a mobile phone, may be configured to allow placement of the antennas fed by these modules such that individual antennas are not substantially perturbed by adjacent antennas.

The first module 702 may include a first input port 733 for receiving MB Tx signal, a second input port 731 for receiving HB Tx signal, a first pair of output ports 740 for outputting MB PRx signals, a second pair of output ports 741 for outputting HB PRx signals, and a third input port 707 for receiving an SRS (e.g., within n41 band) used for establishing MIMO communication via the first and second antennas 706, 708.

The first module 702 may be configured to provide reconfigurable frequency selective RF paths from the first and second input ports 733, 731 to the first and second antennas 706, 708, and from the first and second antennas 706, 708 to the two pairs of output ports 740, 741. The first and second antennas 706, 708, may be connected to the first module 702 via two antenna ports.

The first module 702 may further include an antenna switch 730, a first power amplifier 714a configured to amplify MB Tx signals, a second power amplifier 714b configured to amplify HB Tx signals, a first filter 720a (e.g., bandpass filter) configured to pass MB1 Tx/PRx signals, a second filter 720b (e.g., bandpass filter) configured to pass HB1 Tx/PRx signals, a first duplexer 721a for duplexed transmission of MB2 Tx/PRx signals, a second duplexer 721b for HB2 Tx/PRx for duplexed transmission of MB2 Tx/PRx signals, first and second low noise amplifiers (LNA) 716a, 716b, configured to amplify MB PRx signals, third and fourth LNAs 716c, 716d, configured to amplify HB PRx signals, a first switch 717a configured to selectively connect the power amplifier 714a and the LNA 716a to the first filter 720a and the first duplexer 721a, and a second switch 717b configured to selectively connect the power amplifier 714b and the third LNA 716c to the second filter 720b and the second duplexer 721b.

In some embodiments, the first module 702 may include a fourth input port 750 for outputting/inputting signals within a low frequency band (LB) and fifth input port 751 for outputting/inputting signals within an ultra-high frequency band (UHB). In these impediments, the first module 702 also includes a third duplexer 721c (which is also referred to as an antenna-plexer) between the antenna switch 730 and the first antenna 706 and a fourth duplexer 721d (which can also be referred to as an antenna-plexer) between the antenna switch 730 and the second antenna 708. The third duplexer 721c can be configured to allow simultaneous connection (e.g., duplexed connection) between the fourth input port 750 and the antenna switch 730, with the first antenna 706. The fourth duplexers 721d can be configured to allow simultaneous connection (e.g., duplexed connection) between the fifth input port 751, and the antenna switch 730, with the second antenna 708.

The second module 704 may include a first pair of output ports 742 for outputting MB DRx signals, a second pair of output ports 743 for outputting HB DRx signals, and a first input port 705 for receiving an SRS (e.g., within n41 band) used for establishing MIMO communication via the third and fourth antennas 710, 712.

The second module 704 may be configured to provide reconfigurable frequency selective RF paths from the third and fourth antennas 710, 712 to the two pairs of output ports 742, 743. The third and fourth antennas 710, 712, may be connected to the second module 704 via two antenna ports.

The second module 704 may further include a second antenna switch 732, a first pair of filters 722a, 722b (e.g., bandpass filters) configured to pass MB1 and MB2 DRx signals, respectively, a second pair of filters 722c, 722d (e.g., bandpass filters) for HB1 and HB2 DRx signals, respectively, first and second low noise amplifiers (LNA) 718a, 718b, configured to amplify MB DRx signals, and third and fourth LNAs 718c, 718d, configured to amplify HB DRx signals.

In some embodiments, the second module 704 may include a second input port 752 for outputting/inputting signals within a low frequency band (LB) and third input port 753 for outputting/inputting signals within an ultra-high frequency band signal (UHB). In these impediments, the second module 704 also includes a first duplexer 723a (also referred to as an antenna-plexer) between the antenna switch 732 and the third antenna 710 and a second duplexer 723b between the antenna switch 732 and the fourth antenna 712. The first duplexer 723a can be configured to allow simultaneous connection (e.g., a duplexed connection) between the second input port 752 and the antenna switch 732, with the third antenna 710. The fourth duplexers 723b is configured to allow simultaneous connection (e.g., a duplexed connection) between the fifth port 753, and the antenna switch 732, with the fourth antenna 712.

In some embodiments, radio frequency (RF) font-end RF system 700 may include a circuit 760 configured to provide an SRS (e.g., within n41 band) to the first module 702 (e.g., via the third input port 707) and/or the second module 704 (e.g., via the first input port 705). The circuit 760 may include a power amplifier 755 that receives the SRS signals and a bandpass filter 725 that filters the amplified SRS and provides the amplified and filtered SRS to a switch (or power divider) 727 configured to transmit the received SRS (or a portion of the SRS) to the third input port 707 of the first module 702 and/or to the first input port 705 of the second module 704. In some embodiments, the switch 727 can be electrically connected to the first and second modules 702, 704, via two separate signal traces (e.g., conductive lines or cables) 729a, 729b. The antenna switch 730 can be configured to sequentially transmit the SRS signals received from the third input port 707 of the first module to the first and second antennas 706, 708, and the antenna switch 732 can be configured to sequentially transmit the SRS signals received from the first input port 705 of the second module 704 to the third and fourth antennas 710, 712. The SRS provided to each antenna may be configured to determine and/or update an RF channel model for that antenna. In some embodiments, an SRS signals may comprise known symbols usable for determining a transfer function for modeling the corresponding RF channels (e.g., in terms of phasing, reflections, and fading across the respective bandwidth). In some examples, different SRS signals may be provided to different antennas (e.g., comprising different symbols).

In some embodiments, the output of the switch 727 can be connected to the first input port 705 of the second module 704 and the third input port 707 of the first module 702 via a two signal trances, cables, or other conductive links. In some embodiments, the positioning of the first and second modules 702, 704 within the RF font-end system 700 (e.g., within the corresponding UE) can result in the first and second modules 702, 704 being far from each other and at least one of the first and second modules being far from the circuit that provides the SRS (e.g., the circuit that includes the power amplifier 755, filter 725 and the switch 727). For example, each module can be close to the pair of antennas connected to the module and the two pair of antennas 706/708 and 710/712 can be mounted on different corners, sides, or otherwise locations of the UE. In some cases, the length of a signal trace or electrical link between the first module 702 and/or 704 and the circuit 760 that provides the SRS can be relatively long, making it difficult to isolate the active SRS path from the DL path(s), as is described in further detail below. In some embodiments, the first and second modules 702, 704 may be fabricated on different PCBs and positioned at different locations of UE.

Absent an antenna puncturing mitigation technique, when a SRS is transmitted to one of the antennas 706, 708, 710, 712, a DL channel established via that antenna may be interrupted because the filters and duplexers may not be able to sufficiently isolate the SRS from the respective DL paths receiving PRx or DRx signals from the antenna currently transmitting the SRS.

It should be understood that, to switch combine filters and/or duplexers for transmitting and receiving signals in band signals while blocking an intervening out of band signal (e.g., the SRS), the input impedance of the filters and/or duplexers for the SRS should be deterministic and stable. In the embodiment of the RF front end system 700, because the SRS is provided by an external circuit 760 with respect to the first and second modules 702, 704, such stable and deterministic input impedance may be difficult to establish during SRS transmission. As described above, the first and second modules 702, 704 can be far from each other and at least one of them can be far from the circuit 760 that provides the SRS. Signal traces or other electrical links between modules can result in RF loss, random variation of changes of phase, or otherwise random or temporal changes of properties of the signal transmitted by the link (e.g., due to temperature variations or fluctuations) resulting in unstable impedance transformation between the circuit that provides the SRS and at least one of the first and second modules 702, 704. As such, switch combining multiple antennas to DL paths and SRS paths such that the isolation is maintained between the SRS and DL paths during simultaneous DL communication and SRS activation can be a challenging task.

In some scenarios, even losing one receiver antenna can significantly degrade the performance of the UE. In some implementations, in MIMO communication, when one of the antennas is interrupted the system cannot resolve multiple overlapping received signals having the same frequency. For example, in a 4×4 MIMO communication scenario, the system has to determine four unknown variables (one for each antenna) based on four electromagnetic snapshots received from 4 antennas. When signal reception by one of the antennas is interrupted for SRS transmission, only 3 snapshots will be available. The system cannot determine 4 unknown variables using 3 snapshots (the problem is equivalent to finding the values of 4 unknown variables using only 3 equations). As such, the impact of antenna puncture can be beyond a single antenna affected for a short time.

In some implementations, the antenna puncturing problem may be addressed by adding a 5th antenna that can be dedicated to the MB Tx and PRx without any n41 DL support, so that n41 is not required to “take-over” that antenna and the MB link can be preserved undisturbed. However, given the limited volume and footprint of the UE, including additional antenna reduces the space dedicated to individual antennas and can adversely impact the performance of all antennas of the UE. Additionally, an extra antenna adds hardware and can increase UE power consumption as the fifth antenna may be fed by additional switch connections, filters, and each additional component adds to total power loss in the UE.

The inventors have discovered that by combining and integrating the primary and diversity RF paths within a single module of the RF front end system, the frequency selective RF paths within the single module can be configured (e.g., dynamically during an SRS transmission period), to provide SRS signals to all antennas connected to the module without interrupting the reception of DL signals via a DL RF paths established in the module. To take advantage of these and other inventive aspects discovered by the inventors, one aspect of the disclosed technology includes a single module comprising filters and switches for establishing frequency selective RF paths for receiving both primary and diversity signals from each antenna connected to the module while transmitting SRS via the same antenna. As such the disclosed modules may overcome antenna puncturing, e.g., by switch combining the primary and diversity channels for enhanced CA and SRS support.

Additionally, the SRS signals are provided to the antenna by the same components of the module that transmit and receive signals over one of the frequency bands (e.g., a high frequency band) used by the module for communicating with the baseband stations. In contrast to the first module 702 of the RF front end system 700, that includes one transmission path and one receiving path (1T1R) for each carrier frequency with the respective frequency band, the modules described below can include one transmission path and two receiving paths (1T2R) for each carrier frequency within the respective frequency band. In some examples, the two receive paths may comprise a primary receive path, and a diversity receive path. These modules leverage usage of different combinations of the filters to establish the additional receive paths while allowing transmission of SRS signals to the respective antennas.

In some embodiments, the RF front system may additionally include a MIMO module configured to transmit EN-DC signals (e.g., within n41 frequency band) and support MIMO communication withing one or more frequency bands (e.g., a MB band and am HB band).

FIG. 8 is a schematic diagram of an embodiment of a module of a radio frequency (RF) font-end system, the module having combined primary and diversity receiver circuitry in a single module.

In one embodiment, first RF front end module 900 supports wireless communication via at least two frequency bands, e.g., a mid-frequency band (MB) and a high-frequency band (HB). In some examples, first RF front end module 900 may establish communication over two sub-bands within a first frequency band (e.g., MB1 and MB2) and over two sub-bands within the second frequency band (e.g., HB1 and HB2). In some embodiments, the first RF front end module 900 may support at least one transmit channel UL signals and two receive channels for DL signals (e.g., a primary channel and a diversity channel) within each of these frequency bands or frequency sub-bands. In some examples, the mid-frequency band (MB) can be LTE B25 and the high-frequency band (HB) can be 5G n41.

First RF front end module 900 may include, a first input port 930 for receiving MB Tx signal, a second input port 931 for receiving HB Tx signal, a first pair of output ports 920 for outputting MB PRx signals, one or more output ports (e.g., three output ports) 922 for outputting MB DRx signals, a second pair of output ports 924 for outputting HB PRx signals, and one or more output ports (e.g., two output ports) 926 for outputting HB DRx signals.

First RF front end module 900 may be configured to provide reconfigurable frequency selective RF paths from the first and second input ports 930, 931 to the first and second antennas 902, 904, and from the first and second antennas 902, 904 to the two pairs of output ports 920, 924 and the output ports 922, 926. The first and second antennas 902, 904, may be connected to the first RF front end module 900 via two antenna ports.

First RF front end module 900 may further include a frequency selective RF path switch 906, a first power amplifier 910a configured to amplify MB Tx signals, a second power amplifier 910b configured to amplify HB Tx signals, a first and second low noise amplifiers (LNA) 912a,912b, configured to amplify MB PRx signals, third, fourth, and fifth LNAs 912c, 912d, 912e configured to amplify MB DRx signals, a sixth and seventh LNAs 912f, 912g, configured to amplify HB PRx signals, eighth and ninth LNAs 912h, 912i configured to amplify HB DRx signals, a first amplifier switch 908a configured to selectively connect the first power amplifier 910a and the LNA 912a to the frequency selective RF path switch 906, and a second amplifier switch 908b configured to selectively connect the power amplifier 910b and the LNA 912f to the frequency selective RF path switch 906.

In some embodiments, first RF front end module 900 may include a third input port 916 for outputting/inputting signals within a low frequency band (LB) and fourth input port 918 for outputting/inputting signals within an ultra-high frequency band (UHB). In these impediments, the first RF front end module 900 also includes a first antenna-plexer 914a (e.g., a duplexer) between the frequency selective RF path switch 906 and the first antenna 902 and a second antenna-plexer 914b (e.g., a duplexer) between the frequency selective RF path switch 906 and the second antenna 904. The second antenna-plexer 914a can be configured to allow simultaneous connection (e.g., duplexed connection) between the third input port 916 and the frequency selective RF path switch 906, with the first antenna 902. The second antenna-plexer 914b can be configured to allow simultaneous connection (e.g., duplexed connection) between the fourth input port 918 and the frequency selective RF path switch 906, with the second antenna 904.

In some embodiments, the first RF front end module 900 can be configured to transmit first uplink signals over a first frequency (e.g., MB) band and second uplink signals over a second frequency band (e.g., HB), and receive primary and diversity down link signals (e.g., MB PRx and MB DRx) over the first frequency band and primary and diversity down link signals (e.g., HB PRx and HB DRx) over the second frequency band. In some cases, the first frequency band includes frequencies lower than that of the second frequency band.

The frequency selective RF path switch 906 may transmit first primary downlink (DL) signals (MB PRx) and first diversity downlink signals (MB DRx) from at least one of the two antennas 902, 904 to the first pair of LNAs 912a/b and LNAs 912c/912d/912e, respectively, and transmit second primary downlink signals (HB PRx) and second diversity downlink signals (HB DRx) from at least one of the two antennas 902, 904 to the second pair of LNAs 912f/912g and LNAs 912h/i, respectively. In some cases, the first DL signals (DL1) can be within a first downlink frequency band and the second DL signals (DL2) can be within a second downlink frequency band.

In various implementations, the frequency selective RF path switch 906 may comprise an antenna switch, one or more band pass filers, one or more switches, and one or more multiplexers (e.g., duplexers, triplexers, or the like) configured to provide frequency selective RF paths between the first and second antennas, and the amplifiers of the first radio frequency module. The switches may be controlled during different modes of operation to dynamically configure the frequency selective RF paths for various signals transmitted and/or received by first RF front end module 900 (e.g., SRS, TRx, PRx, DRx, . . . ). In particular during an antenna calibration or antenna model update period, the amplifier switches, and antenna switches of the RF path switch 906 may be configured (e.g., by a controller module, or the UE), to provide SRS signals to an antenna without interrupting the DL signals received by the antenna.

During an antenna calibration period, the frequency selective RF path switch 906 may transmit SRS signals from a power amplifier within first RF front end module 900 to the first and the second antennas 902, 904, to evaluate a channel model for each of the antennas. In some examples, the SRS signals may be transmitted sequentially.

In some examples, the SRS signals can be signals within a high frequency band supported by the first RF front end module 900 and therefore provided by a power amplifier associated with the high frequency band (e.g., power amplifier 910b).

The frequency selective RF path switch 906 can be configured to simultaneously transmit a first SRS from the second power amplifier 910b to the first antenna 902 and receive a primary or a diversity downlink signals (MB PRx, MB DRx, HB PRx or HB DRx) from the first antenna 902. Similarly, the frequency selective RF path switch 906 can be configured to simultaneously transmit a second SRS from the second power amplifier 910b to the second antenna 904 and receive a primary or a diversity downlink signals (MB PRx, MB DRx, HB PRx or HB DRx) from the second antenna 904.

In some embodiments, the frequency selective RF path switch 906 may enable ganging HB (e.g., n41) and MB (e.g., B25) PRx signals as well as HB (e.g., n41) and MB (e.g., B25) DRx signals to keep the MB anchor connected to the first antenna 902.

In some embodiments, a RF front end system may include first RF front end module 900 and an additional module configured to receive SRS signals from first RF front end module 900 for updating antenna models for the antennas therein. In some examples, the additional module may be configured for EN-DC (e.g., over n41 frequency band) communication using MIMO transmit EN-DC signals and receive SRS signals from module 900, to the antennas therein.

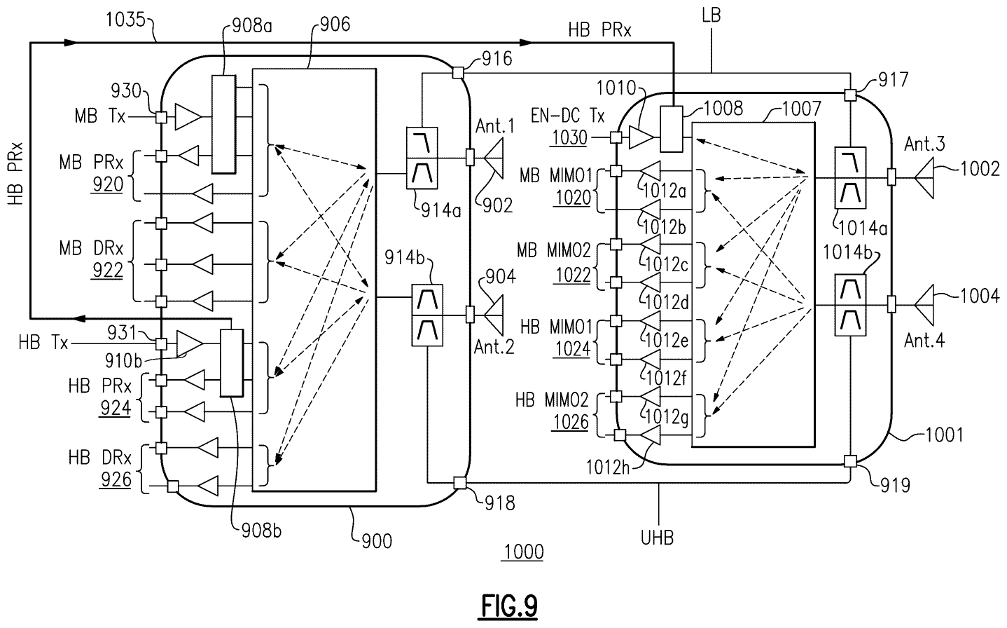

FIG. 9 is a schematic diagram of an embodiment of a radio frequency (RF) font-end system including first RF front end module 900 and a second RF front end module 1001 (e.g., an EN-DC MIMO module).

In one embodiment, second RF front end module 1001 supports wireless MIMO communication via at least two frequency bands, e.g., a mid-frequency band (MB) and a high-frequency band (HB). In some examples, second RF front end module 1001 may establish communication over two or more sub-bands within a first frequency band (e.g., MB1 and MB2) and over two or more sub-bands within the second frequency band (e.g., HB1 and HB2). In some embodiments, second RF front end module 1001 may support a transmit channel for UL EN-DC Tx signals and one or more receive channels for DL signals within each of the at least two frequency bands or corresponding frequency sub-bands. In some examples, the mid-frequency band (MB) can be LTE B25 and the high-frequency band (HB) can be 5G n41.

Second RF front end module 1001 may include an input port 1030 for receiving EN-TC Tx signals, a first pair of output ports 1020 for outputting MB MIMO1 Rx signals, a second pair of output ports 1022 for outputting MB MIMO2 Rx signals, a third pair of output ports 1024 for outputting MB MIMO3 Rx signals, a fourth pair of output ports 1026 for outputting MB MIMO4 Rx signals.

Second RF front end module 1001 may be configured to provide reconfigurable frequency selective RF paths from the input port 1030 to third and fourth antennas 1002, 1004 of the RF front end module 1001, and from the third and fourth antennas 1002, 1004 to the four pairs of output ports 1020, 1022, 1024, and 1026. The third and fourth antennas 1002, 1004, may be connected to the second RF front end module 1001 via two antenna ports.

Second RF front end module 1001 may further include a frequency selective RF path switch 1007, a power amplifier 1010 configured to amplify EN-DC Tx signals, a first, second, third and fourth low noise amplifiers (LNA) 1012a, 1012b,1012c and 1012d configured to amplify MINO1 Rx and MIMO2 Rx signals within a mid-frequency band (MB), fifth, sixth, seventh, and eight LNAs 1012e, 1012f, 1012g, 1012h configured to amplify MIMO3 Rx and MIMO4 Rx signals within a high-frequency band (HB), a amplifier switch 1008 configured to selectively connect the power amplifier 1010 an input received from the first RF front end module 900 to the frequency selective RF path switch 1007. In some embodiments, the amplifier switch 1008 can be connected to the second amplifier switch 908b of the first RF front end module 900 via signal trance (e.g., a conductive line) 1035 and can be configured to receive SRS from the first RF front end module 900 (e.g., from the power amplifier 714b of the module 900).

The frequency selective RF path switch 1007 may establish MIMO communication via antennas 1002, 1004 for transmitting EN-DC Tx uplink signal, and transmitting downlink MIMO signals from the two antennas 1002, 1004 to the LNAs 1012a-1012g.

In various implementations, the frequency selective RF path switch 1007 may comprise an antenna switch, one or more band pass filers, one or more switches, and one or more multiplexers (e.g., duplexers, triplexers, or the like) configured to provide frequency selective RF paths between the third and fourth antennas 1002, 1004 and amplifiers of second RF front end module 1001. The switches may be controlled during different modes of operation to dynamically configure the frequency selective RF paths for various signals transmitted and/or received by second RF front end module 1001 (e.g., SRS, TRx, PRx, . . . ). In particular during an antenna calibration period or antenna model update period, the switches and the antenna switch of the RF path switch 1007 may be configured (e.g., by a controller of second RF front end module 1001, or the UE), to allow SRS signals to be provided to an antenna without interrupting the DL signals received by the antenna.

During an antenna calibration period, the frequency selective RF path switch 1007 may transmit SRS signals received by the second RF front end module 1001 (e.g., via the signal trace 1035) from the first RF front end module 900 to the third and fourth antennas 1002, 1004, to evaluate a channel model for each of these antennas. In some examples, the SRS signals may be transmitted sequentially (e.g., a first SRS to the third antenna 1002 and a second SRS to the fourth antenna 1004).

In some examples, the SRS signals can be signals within a high frequency band supported by second RF front end module 1001 (e.g., n41) and therefore provided by a power amplifier of the first RF front end module 900 associated with the high frequency band (e.g., power amplifier 910b).

The frequency selective RF path switch 1007 can be configured to simultaneously transmit a first SRS from the second power amplifier 910b of first RF front end module 900 to the third antenna 1002 and receive downlink signals (MB MIMO1/MIMO2 or HB MIMO1/MIMO2) from the third antenna 1002. Similarly, the frequency selective RF path switch 1007 can be configured to simultaneously transmit a second SRS from the second power amplifier 910b of first RF front end module 900 to the fourth antenna 1004 and receive downlink signals (MB MIMO1/MIMO2 or HB MIMO1/MIMO2) from the fourth antenna 1004.

In some embodiments, the second RF front end module 1001 may include a second input port 917 for outputting/inputting signals within a low frequency band (LB) and third input port 919 for outputting/inputting signals within an ultra-high frequency band (UHB). In these impediments, second RF front end module 1001 also includes a first antenna-plexer 1014a (e.g., a duplexer) between the frequency selective RF path switch 1007 and the third antenna 1002 and a second antenna-plexer 1014b (e.g., a duplexer) between the frequency selective RF path switch 1007 and the fourth antenna 1004. The second antenna-plexer 1014a can be configured to allow simultaneous connection (e.g., duplexed connection) between the second input port 917 and the frequency selective RF path switch 1007, with the third antenna 1002. The second antenna-plexer 1014b can be configured to allow simultaneous connection (e.g., duplexed connection) between the third input port 919 and the frequency selective RF path switch 7007, with the fourth antenna 1004.

In some embodiments, the operation of the RF front end system 1000 may be capable of EN-DC operation that avoids two simultaneous active power amplifiers in the same module for performance-related isolation considerations. In some embodiments, the power amplifier 910b of the first RF front end module 900 (e.g., an LFEM module) may provide SRS signals to all 4 antennas 902, 904, 1002, and 1004 in a specific sequence. In some examples, the sequence may include providing a first SRS comprising first symbols (Sym. #1) to the first antenna 902, providing a second SRS comprising second symbols (Sym. #2) to the second antenna 904, providing a third SRS comprising third symbols (Sym. #3) to the third antenna 1002, and providing a fourth SRS comprising fourth symbols (Sym. #1) to the fourth antenna 1004 (as show in Table 1 below).

| First RF front end module 900 | | | | Second RF front end module 1001 | | | |
|---|---|---|---|---|---|---|---|
| Antenna 1 | | Antenna 2 | | Antenna 3 | | Antenna 4 | |
| MB | n41Tx | MB LTE | | MB LTE | | MB LTE | |
| LTE | Sym. | DRx | | MIMO1, | | MIMO2, | |
| Tx/PRx | #1 | | | Rx | | Rx | |
| MB | | MB LTE | n41Tx | MB LTE | | MB LTE | |
| LTE | | DRx | Sym. | MIMO1, | | MIMO2, | |
| Tx/PRx | | | #2 | Rx | | Rx | |
| MB | | MB LTE | | MB LTE | n41Tx | MB LTE | |
| LTE | | DRx | | MIMO1, | Sym. | MIMO2, | |
| Tx/PRx | | | | Rx | #3 | Rx | |
| MB | | MB LTE | | MB LTE | | MB LTE | n41Tx |
| LTE | | DRx | | MIMO1, | | MIMO2, | Sym. #4 |
| Tx/PRx | | | | Rx | | Rx | |

In some cases, by integrating the primary and diversity RF paths in the RF front end module 900, the RF front end system 1000 can control the amplifier switches 908a, 908b, 1008, and antenna switches 906, 1007 to switch combine together the HB Tx (e.g., n41 Tx) and MB Rx or MB DRx (e.g., B25 Rx) RF path as shown in the table 1 to support connection of HB Tx to all 4 antennas. As the HB Tx is directed to a different antenna, the MB PRx, DRx, MIMO1 Rx, and MIMO2 Rx can be all static and remain connected to the respective antennas and the HB Tx is switch-combined in with them. The amplifier switches 908b and 1008 together can enable connection of a signal output by the power amplifier 910b to be provided to the input of HB Tx-capable filters, such as an n41 filter (not shown in FIG. 9), within the frequency selective RF path switches 906, 1007, that can be configured to be switch-combined with MB PRx, DRx, MIMO1 Rx, and/or the MIMO2 Rx filters within the frequency selective RF path switches 906, 1007. In some examples, a HB Tx-capable filter within the frequency selective RF path switch 906 can be switch-combined with, e.g., a MB PRx filter, to support both the HB Tx and MB Rx (e.g., the HB Tx filter can be shared between Tx and Rx signal paths). For example, an active n41 UL path and an active B25 DL path can share a single antenna feed. The combinations in the respective modules operate similarly for the MB DRx, MIMO1 Rx, and MIMO2 Rx filters combined with n41.

Advantageously, the RF front system 1000 can support various EN-DC combinations within the MHB band group while not suffering the puncturing or blanking of the anchor when the HB PRx (e.g., n41 Tx) has to take-over a specific antenna a SRS and enables such functionality without filter duplication resulting in a cost-effective performance improvement.

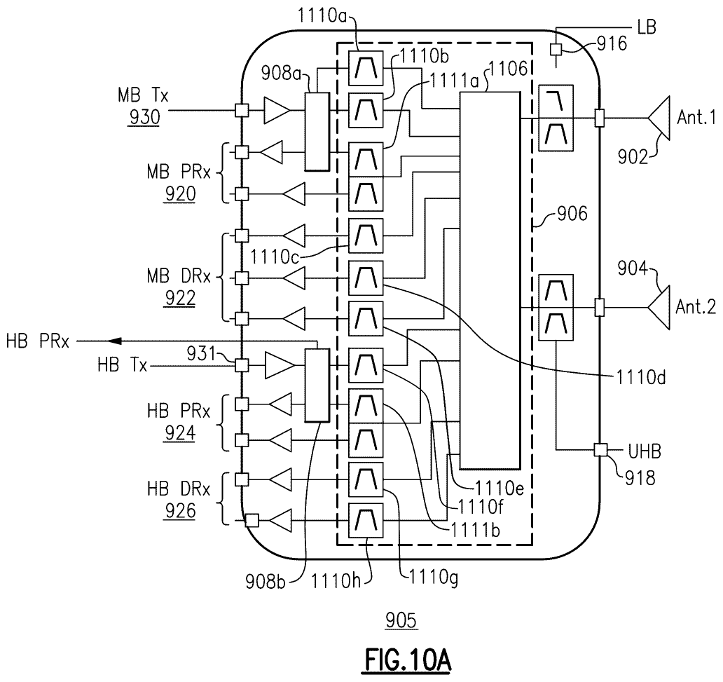

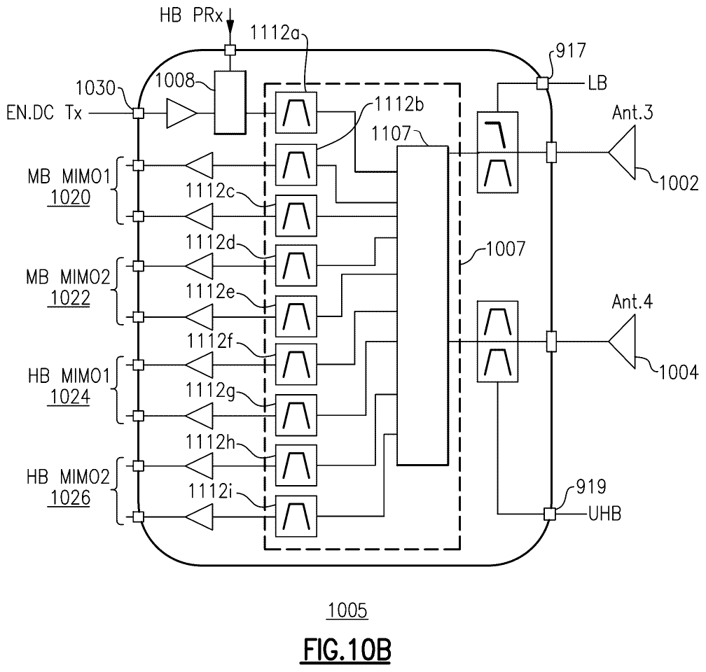

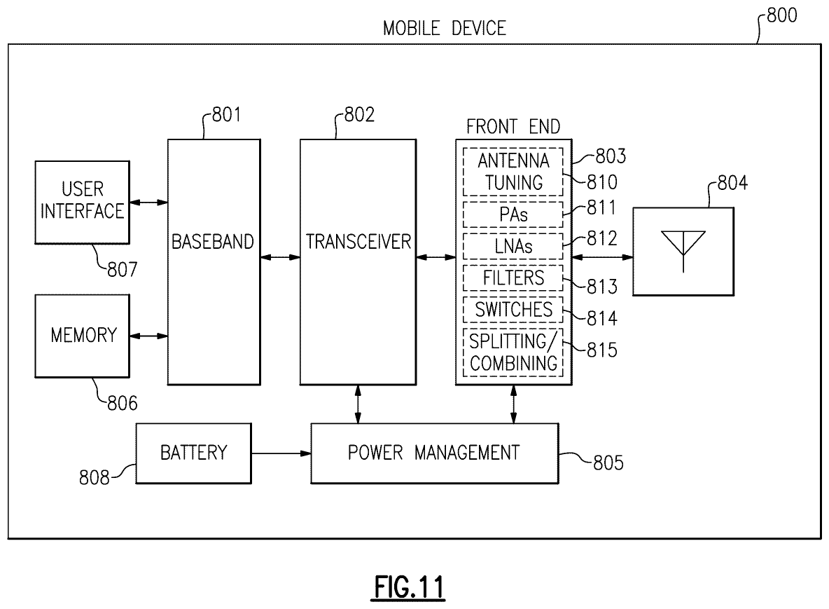

FIG. 10A is a schematic diagram of an RF front-end module 905 that is an example implementation of the first RF front end module 900 described above with respect to FIG. 9. In some embodiments, RF front-end module 905 can include the features and components described above with respect to the first RF front end module 900. In one embodiment, the frequency selective RF path switch 906 of the RF front-end module 905 includes an antenna switch 1106 comprising a plurality of filter ports and two antenna ports and a plurality of filters (e.g., duplexers, triplexers, and the like). In some examples, each of these antenna ports is connected (e.g., electrically connected) to one of the antennas 902, 904, and the plurality of filters provide connections between the first and second amplifier switches 908a, 908b and the LNAs of the frequency selective RF path switch 906.

As described above, in some implementations, each output port of the antenna switch 1106 can be connected to one of the antennas 902, 904 via a duplexer configured to connect that antenna to a port (input/output ports 916, 918) of the RF front end module 905 for receiving and/or transmitting signals to/from a module external to the RF front end module 905 (e.g., a module for communicating signals within a LB or an UHB band).

In one embodiment, the plurality of filters of the frequency selective RF path switch 906 can include first and second filters (e.g., bandpass filters) 1110a, 1110b configured to connect one filter port to the first amplifier switch 908a, a first duplexer 1111a configured to connect a filter port to the first amplifier switch 908a and an LNA outputting MB PRx signals, third, fourth, and fifth filters (e.g., bandpass filters) 1110c, 1110d, 1110e configured to connect three filter ports to three LNAs outputting MB DRx signals, a sixth filter (e.g., bandpass filters) 1110f configured to connect one filter port to the second switch 908b, a second duplexer 1111b configured to connect a filter port to the second amplifier switch 908b and an LNA outputting HB PRx signals, seventh and eight filters (e.g., bandpass filters) 1110g and 1110h configured to connect two filter ports to two LNAs outputting HB DRx signals.

FIG. 10B is a schematic diagram of an RF front-end module 1005 that is an example implementation of the second RF front end module 1001 described above with respect to FIG. 9. In some embodiments, RF front-end module 1005 can include the features and components described above with respect to the second RF front end module 1001. In one embodiment, the frequency selective RF path switch 1007 of the RF front-end module 1005 includes an antenna switch 1107 comprising a plurality of filter ports and two antenna ports and a plurality of filters (e.g., duplexers, triplexers, and the like). In some examples, each of these antenna ports is connected (e.g., electrically connected) to one of the antennas 1002, 1004, and the plurality of filters provide connections between the amplifier switch 1008 and the LNAs of the frequency selective RF path switch 1007.

As described above, in some implementations, each output port of the antenna switch 1107 can be connected to one of the antennas 1002, 1004 via a duplexer configured to connect that antenna to a port (input/output ports 917, 919) of the RF front end module 1005 for receiving and/or transmitting signals to/from a module external to the RF front end module 1005 (e.g., a module for communicating signals within a LB or an UHB band).

In one embodiment, the plurality of filters of the frequency selective RF path switch 1007 can include a first filter 1112a configured to connect one filter port to the amplifier switch 1008, second and third filters 1112b, 1112c configured to connect two filter ports to two LNAs outputting MB MIMO1 signals, fourth and fifth filters 1112d, 1112e configured to connect two filter ports to two LNAs outputting MB MIMO2 signals, sixth and seventh 1112f, 1112g filters configured to connect two filter ports to two LNAs outputting HB MIMO1 signals, eight and nineth filters 1112h, 1112i configured to connect two filter ports to two LNAs outputting HB MIMO2 signals.

The antenna switch 1106 can be configured to controllably connect one more of its filter ports to any one of its antenna ports. In various implementations, antenna switch 1106 can be configured to simultaneously connect two or more of its filter ports to one or both if its antenna ports or provide any other connection arrangement that may establish RF paths for transmitting UL signals or SRS signals and receiving DL signals. In some embodiments, the amplifier switch 908b and the antenna switch 1106 can be configured to establish one or more RF paths between one or more of its filter ports and one of its antenna ports connected to one of the antennas 902, 904 to establish RF paths for simultaneous or concurrent reception of a DL signal from that antenna and transmission of a SRS to that antenna. For example, the HB Tx-capable filter 1110e can be switch-combined with, e.g., the MB PRx 1111a filter, to support both the HB Tx (e.g., the SRS signal) and MB Rx via the first antenna.

The antenna switch 1107 can be configured to controllably connect one more of its filter ports to any one of its antenna ports. In various implementations, antenna switch 1107 can be configured to simultaneously connect two or more of its filter ports to one or both of its antenna ports or provide any other connection arrangement that may establish RF paths for transmitting UL signals or SRS signals and receiving DL signals. For example, the antenna switch 1107 can be configured to establish one or more RF paths between one or more of its filter ports and one its antenna ports connected to one of the antennas 1002, 1004 to establish RF paths for simultaneous or concurrent reception of a DL signal (e.g., MB MIMO1/MIMO2 or HB MIMO1/MIMO2) from that antenna and transmission of a SRS (e.g., HB PRx received from the first RF front end module 900) to that antenna.

As described above with respect to Table 1, the RF front end system 1000 may provide SRS signals to all 4 antennas 902, 904, 1002, and 1004 in a sequence. In some embodiments, when RF front system 1000 is formed by combining RF modules 905 and 1005 (e.g., connecting the HB PRx output by amplifier switch 908 to the amplifier switch 1008), antenna switches 1106 and 1107 can be dynamically reconfigured, e.g., by a processor of the RF front end system 1000 or a processor of the corresponding UE, to send four SRS signals sequentially to the first, second, third, and fourth antennas 902, 904, 1002 and 1004 according to the procedure described below:

In the first SRS period, antenna switch 1106 may be configured to simultaneously or concurrently provide: 1) a first RF path between the first antenna 902 and the switch 908b to allow a first SRS in n41 band to be transmitted via the first antenna 902, 2) a second RF path between the first antenna 902 and one of the LNAs connected to a first output port of the first pair of output ports 920 to receive a first MB PRx DL signal, 3) a third RF path between the first antenna 902 and a second LNA connected to a second output port of the first pair of output ports 920 to receive a second MB PRx DL signal, and 4) fourth, 5) fifth, and 6) sixth RF paths between the first antenna 902 and the three LNAs connected to the output port 922 to receive first, second and third MB DRx DL signals, respectively.

In the second SRS period, antenna switch 1106 may be configured to simultaneously or concurrently provide: 1) a first RF path between the second antenna 904 and the switch 908b to allow a second SRS in n41 band to be transmitted via the second antenna 904, 2) a second RF path between the second antenna 904 and one of the LNAs connected to a first output port of the second pair of output ports 924 to receive a first HB PRx DL signal, 3) a third RF path between the second antenna 904 and a second LNA connected to a second output port of the second pair of output ports 924 to receive a second HB PRx DL signal, and 4) fourth and 5) fifth RF paths between the second antenna 904 and the two LNAs connected to the output ports 926 to receive first and second HB DRx DL signals, respectively.

In a third SRS period, antenna switch 1107 may be configured to simultaneously or concurrently provide: 1) a first RF path between antenna 1002 and the amplifier switch 1008 to allow a first SRS in n41 band to be transmitted via the third antenna 1002, 2) a second RF path between the third antenna 1002 and one of the LNAs connected to a first output port of the first pair of output ports 1020 to receive a first MB MIMO1 DL signal, 3) a third RF path between the third antenna 1002 and a second LNA connected to a second output port of the first pair of output ports 1020 to receive a second MB MIMO1 DL signal,

In a fourth SRS period, antenna switch 1107 may be configured to provide: 1) a first RF path between the fourth antenna 1004 and the amplifier switch 1008 to allow a second SRS in n41 band to be transmitted via the fourth antenna 1004, 2) a second RF path between the fourth antenna 1004 and one of the LNA connected to a first output port of the second pair of output ports 1022 to receive a first MB MIMO2 DL signal, and 3) a third RF path between the fourth antenna 1004 and a second LNA connected to a second output port of the second pair of output ports 1022 to receive a second MB MIMO2 DL signal.

As such the antenna switches 1106, 1107 can enable multi-on operation to switch combine filters in various combinations in the respective RF modules to enable transmission of SRS signals in n41 band via all four antennas 902, 904, 1002, and 1004, while providing DL RF paths to maintain reception of primary MB/HB signals, diversity HB/MB signals, MB MIMO1/MIMO2 signals, and HB MIMO1/MIMO2 signals. In some implementations, the SRS signals in n41 sent to different antennas can include different symbols. In some embedment, the SRS signals (e.g., in n41 band) sent to at least two different antennas of the RF front system 1000 can include different symbols. In some implementations, the SRS signals (e.g., in n41 band) sent to at least two different antennas of the RF front system 1000 can include different symbols. In some implementations, the SRS signals (e.g., in n41 band) sent to at least two different antennas in the same module (e.g., RF module 905 or RF module 1005) of the RF front system 1000 can include different symbols.

In various implementations, both RF front end modules 905 and 1005 are designed to have one transmission channel and two receiving channels (1T2R). In some cases, the integration of primary and diversity channels in the RF front end module 905 enables a more efficient switch-combination of the Tx-capable n41 filter with filters associated with MB PRx and MB DRx signals. For example, ganging HB PRx (e.g., n41 PRx) with MB PRx (e.g., M25), and HB PRx with MB DRx keeps MB anchor connected to the first antenna 902. The additional receive path in the package/module may allow not only switch combining the primary filters but also the diversity receive filters allowing an array of configurations possible. In some cases, the design of the RF front end module 1005 enables EN-DC n41 Tx to be switch-combined with either the MB MIMO1 Rx or the MIMO2 Rx.

In some embodiments, if the receive sensitivity is degraded due to EN-DC operation, intermodulation nonlinear mixing of MB Tx and HB Tx, Tx drive power from RF integrated circuit that provides the Tx signals may be “blanked” to preserve MB PRx integrity.

In various implementations, the configurations and procedures described above can cover NR TDD plus LTE/NR FDD/asynchronous TDD and can be specified (for instance, using data stored in a memory, such as a look-up table) as taking effect when this CA or EN-DC combination occurs so that no takeover/puncturing of the DL path occurs during SRS transmission.

FIG. 11 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808. In some embodiments, the front-end system 803 may comprise the front end system 1000 described above with respect to FIG. 9, and can include any of the embodiments described herein, including those described with respect to FIGS. 5-10B.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 11 as the transceiver 802. In one example, separate components (for instance, separate circuits or dies) can be provided for handling certain types of RF signals. Such separate transceiver circuits or dies can receive separate RF split signals from the front-end systems implemented in accordance with the teachings herein.

The front-end system 803 aids in conditioning signals transmitted to and/or received from the antennas 804. In the illustrated embodiment, the front-end system 803 includes antenna tuning circuitry 810, power amplifiers (PAs) 811, low noise amplifiers (LNAs) 812, filters 813, switches 814, and signal splitting/combining circuitry 815. The front-end system 803 can be implemented in accordance with any of the embodiments herein.

With continuing reference to FIG. 11, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 11, the baseband system 801 is coupled to the memory 806 to facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 11, the power management system 805 receives a battery voltage from the battery 808. The battery 808 can be any suitable battery for use in the mobile device 800, including, for example, a lithium-ion battery.

### Applications

Some of the embodiments described above have provided examples in connection with mobile devices. However, the principles and advantages of the embodiments can be used for a wide range of RF communication systems. Examples of such RF communication systems include, but are not limited to, mobile phones, tablets, base stations, network access points, customer-premises equipment (CPE), laptops, and wearable electronics.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A radio frequency front-end module comprising:
a first transmit amplifier configured to output first uplink signals over a first frequency band, and a second transmit amplifier configured to output second uplink signals over a second frequency band;
a first receive amplifier configured to receive primary downlink signals over the first frequency band, and a second receive amplifier configured to receive diversity downlink signals over the first frequency band; and
a radio frequency switch configured, during an antenna calibration period, to simultaneously: pass the second uplink signals corresponding to one or more sounding reference signal symbols to a first antenna, pass the primary downlink signals from the first antenna to the first receive amplifier, and pass the diversity downlink signals from a second antenna to the second receive amplifier.

2. A radio frequency front-end system comprising the radio frequency front-end module of claim 1 and a second radio frequency front-end module coupled to the radio frequency front-end module to receive the second uplink signals, the second radio frequency front-end module including:
a third receive amplifier configured to receive third downlink signals over the first frequency band, and a fourth receive amplifier configured to receive fourth downlink signals over the first frequency band; and
a second radio frequency switch configured, during another antenna calibration period, to simultaneously: pass the second uplink signals corresponding to one or more second sounding reference signal symbols to a third antenna, pass the third downlink signals from the third antenna to the third receive amplifier, and pass the fourth downlink signals from a fourth antenna to the fourth receive amplifier.

3. A radio frequency front-end system comprising:
a first radio frequency module configured to transmit first uplink signals over a first frequency band and second uplink signals over a second frequency band, and receive primary and diversity downlink signals over the first and second frequency bands, the first radio frequency module including a first radio frequency switch configured to: pass first primary downlink signals and first diversity downlink signals within the first frequency band from at least one of a first antenna and a second antenna to one or more receive amplifiers; pass second primary downlink signals and second diversity downlink signals within the second frequency band from at least one of the first and second antennas to the one or more receive amplifiers; and during an antenna calibration period, simultaneously transmit a first sounding reference signal to the first antenna and pass a primary or a diversity downlink signal from the first antenna to the one or more receive amplifiers.

4. The radio frequency front-end system of claim 3 wherein the first radio frequency switch passes the first sounding reference signal to the first antenna without interrupting an anchor link established based on the first antenna.

5. The radio frequency front-end system of claim 3 wherein the first sounding reference signal is usable for determining a channel model for the first antenna.

6. The radio frequency front-end system of claim 3 wherein the one or more receive amplifiers include:
first and second primary amplifiers configured to receive first and second primary downlink signals, respectively, and
first and second diversity amplifiers configured to receive first and second diversity downlink signals, respectively.

7. The radio frequency front-end system of claim 3 further including first and second power amplifiers configured to provide first and second uplink signals, respectively.

8. The radio frequency front-end system of claim 7 wherein during the antenna calibration period, the first radio frequency switch is configured to simultaneously transmit a second sounding reference signal from the second power amplifier to the second antenna and receive a primary or a diversity downlink signal from the second antenna, the second sounding reference signal configured to determine a channel model for the second antenna.

9. The radio frequency front-end system of claim 3 wherein the first and second sounding reference signals are within the second frequency band.

10. The radio frequency front-end system of claim 7 wherein the first radio frequency switch includes a first antenna switch and a first plurality of radio frequency filters configured to provide frequency selective radio frequency paths between the first and second antennas and at least the one or more receive amplifiers.

11. The radio frequency front-end system of claim 10 wherein the first antenna switch and a first plurality of filters configured to provide frequency selective radio frequency paths between the first and second antennas and the first and second power amplifiers.

12. The radio frequency front-end system of claim 3 wherein the first radio frequency module further includes a first antenna-plexer connecting the first antenna and the first radio frequency switch, the first antenna-plexer configured to provide an external signal within a low frequency band to the first antenna while maintaining communication between the first antenna and the first radio frequency switch.

13. The radio frequency front-end system of claim 7 further comprising a second radio frequency module configured to establish multiple-input multiple-output communication via third and fourth antennas for transmitting third uplink signals over a third frequency band, and receiving downlink signals over the first and second frequency bands, the second radio frequency module including: a second radio frequency switch configured to: pass first downlink signals from at least one of the third and fourth antennas to a first receive amplifier; and pass second downlink signals from least one of the two antennas to a second receive amplifier; and the second radio frequency switch being configured, during the antenna calibration period, to simultaneously transmit a third sounding reference signal received from the first radio frequency module to the third antenna and receive a primary or a diversity downlink signal from the third antenna, the third sounding reference signal configured to determine a channel model for the third antenna.

14. The radio frequency front-end system of claim 13 wherein the first receive amplifier is configured to receive first downlink signals over the first frequency band and the second receive amplifier is configured to receive second downlink signals over the second frequency band.

15. The radio frequency front-end system of claim 13 wherein during the antenna calibration period, the second radio frequency switch is configured to simultaneously transmit a fourth sounding reference signal received from the first radio frequency module to the fourth antenna and receive a primary or a diversity downlink signal from the fourth antenna, the fourth sounding reference signal configured to determine a channel model for the fourth antenna.

16. The radio frequency front-end system of claim 13 wherein the second radio frequency module is further configured to transmit EN-DC transmit signals.

17. The radio frequency front-end system of claim 16 wherein the second radio frequency module further includes a third power amplifier configured to provide the EN-DC transmit signal to the second radio frequency switch through a second switch.

18. The radio frequency front-end system of claim 3 above wherein the first frequency band includes a mid-frequency band and the second frequency band includes a high-frequency band.

19. The radio frequency front-end system of claim 18 wherein the mid-frequency band includes B25 and high-frequency band includes n41.

20. A mobile device comprising:
first and second antennas; and
a first radio frequency module configured to transmit first uplink signals over a first frequency band and second uplink signals over a second frequency band, and receive primary and diversity downlink signals over the first and second frequency bands, the first radio frequency module including a first radio frequency switch configured to: pass first primary downlink signals and first diversity downlink signals within the first frequency band from at least one of a first antenna and a second antenna to one or more receive amplifiers; pass second primary downlink signals and second diversity downlink signals within the second frequency band from at least one of the first and second antennas to the one or more receive amplifiers; and during an antenna calibration period, simultaneously transmit a first sounding reference signal to the first antenna and pass a primary or a diversity downlink signal from the first antenna to the one or more receive amplifiers.
